(19) United States
(12) Patent Application Publication
(10) Pub. No.: US 2026/0344242 A1
(43) Pub. Date: Oct. 29, 2026

(54) DISPLAY DEVICE AND ELECTRONIC DEVICE

(71) Applicant: SEMICONDUCTOR ENERGY LABORATORY CO., LTD., Atsugi-shi (JP)

(72) Inventors: Shunpei YAMAZAKI, Tokyo (JP); Koji KUSUNOKI, Isehara (JP); Daisuke KUBOTA, Atsugi (JP); Taisuke KAMADA, Niiza (JP)

(21) Appl. No.: 19/387,912

(22) Filed: Nov. 13, 2025

Related U.S. Application Data
(63) Continuation of application No. 17/420,496, filed on Jan. 8, 2020, now abandoned.

(30) Foreign Application Priority Data
Jan. 18, 2019 (JP) 2019-006696

(51) Int. Cl. H10K 59/65; G06F 3/042; G09F 9/33; G09G 3/3233; H10K 65/00

(52) U.S. Cl. CPC H10K 59/65; G09F 9/335; H10K 65/00; G06F 3/042; G09G 3/3233; G09G 2300/0426; G09G 2300/0814; G09G 2300/0861

(57) ABSTRACT

A display device having a non-contact input function without contact is provided. A first light-emitting device that performs display, a second light-emitting device that emits light for detection, and a light-receiving device are included, and the light-receiving device has a function of detecting light that has been emitted by the second light-emitting device and reflected by an object. Near-infrared light, which has substantially no visibility, is used as the light emitted by the second light-emitting device. Therefore, the light emitted from a display portion even at high luminance does not affect visual recognition of the display. In addition, when the light is emitted at high luminance, an object that is positioned away from the display device can be detected with high sensitivity.

### CROSS REFERENCE TO RELATED APPLICATIONS

This application is a continuation of U.S. application Ser. No. 17/420,496, filed Jul. 2, 2021, now pending, which is incorporated by reference, and is a U.S. National Phase Application under 35 U.S.C. § 371 of International Application PCT/IB2020/050102, filed on Jan. 8, 2020, which is incorporated by reference and claims the benefit of a foreign priority application filed in Japan on Jan. 18, 2019, as Application No. 2019-006696.

### TECHNICAL FIELD

One embodiment of the present invention relates to a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a driving method thereof, and a manufacturing method thereof.

In this specification and the like, a semiconductor device generally means a device that can function by utilizing semiconductor characteristics. A transistor and a semiconductor circuit are embodiments of semiconductor devices. In some cases, a memory device, a display device, an imaging device, or an electronic device includes a semiconductor device.

### BACKGROUND ART

In recent years, display devices have been applied to various use. Examples of applications of large-sized display devices are television devices for home, digital signage, PID (Public Information Display), and the like. Examples of applications of small- and medium-sized display devices are portable information terminals such as smartphones and tablet terminals.

For example, light-emitting apparatuses including light-emitting devices have been developed as display devices. Light-emitting devices utilizing an electroluminescence (hereinafter referred to as EL) phenomenon have features such as thinness and lightweight, high-speed response, and capability of low-voltage driving. Patent Document 1, for example, discloses a flexible light-emitting apparatus.

### REFERENCE

### Patent Document

[Patent Document 1] Japanese Published Patent Application No. 2014-197522

### SUMMARY OF THE INVENTION

### Problems to be Solved by the Invention

Since display devices are used in a variety of apparatuses as described above, they are desired to have high functionality. For example, a more convenient electronic device can be achieved with a user interface function, an imaging function, or the like.

In view of the above, an object of one embodiment of the present invention is to provide a display device having an input function. Another object is to provide a display device having a function of detecting light. Another object is to provide a multifunctional display device. Another object is to provide a novel display device. Another object is to provide a novel semiconductor device or the like.

Note that the description of these objects does not preclude the existence of other objects. One embodiment of the present invention does not have to achieve all these objects. Other objects are apparent from and can be derived from the description of the specification, the drawings, the claims, and the like.

### Means for Solving the Problems

One embodiment of the present invention is a display device that includes a light-emitting device and a light-receiving device in a display portion

One embodiment of the present invention is a display device including a first pixel, a second pixel, and a third pixel, in which the first pixel includes a first light-emitting device, the second pixel includes a second light-emitting device, the third pixel includes a light-receiving device, the first light-emitting device has a function of emitting visible light, the second light-emitting device has a function of emitting near-infrared light, the light-receiving device has a function of detecting the near-infrared light, and the second pixel has a function of generating a third potential based on a first potential and a second potential and a function of performing light emission of the second light-emitting device in accordance with the third potential.

The first light-emitting device can have a function of emitting light of any of red, green, blue, or white.

It is preferable that the light-receiving device include a photoelectric conversion layer and include an organic compound in the photoelectric conversion layer.

The first light-emitting device, the second light-emitting device, and the light-receiving device can have a structure of a diode, and a cathode of the first light-emitting device, a cathode of the second light-emitting device, and an anode of the light-receiving device can be electrically connected to one another. Alternatively, the cathode of the first light-emitting device, the cathode of the second light-emitting device, and a cathode of the light-receiving device can be electrically connected to one another.

It is preferable that a visible-light cut-off filter be provided in a position overlapping with the light-receiving device.

It is preferable that the first to third pixels include a transistor, the transistor include a metal oxide in a channel formation region, and the metal oxide include In, Zn, and M (M is Al, Ti, Ga, Ge, Sn, Y, Zr, La, Ce, Nd, or Hf).

### Effect of the Invention

According to one embodiment of the present invention, a display device having an input function can be provided. Alternatively, a display device having a function of detecting light can be provided. Alternatively, a multifunctional display device can be provided. Alternatively, a novel display device can be provided. A novel semiconductor device or the like can be provided.

Note that the description of the effects does not preclude the existence of other effects. One embodiment of the present invention does not need to have all these effects. Other effects can be derived from the descriptions of the specification, the drawings, and the claims.

### BRIEF DESCRIPTION OF THE DRAWINGS

FIG. 1 is a diagram illustrating a display device.

FIG. 2A to FIG. 2D and FIG. 2E1 to FIG. 2E3 are diagrams each illustrating the structure of a pixel. FIG. 2F and FIG. 2G are diagrams each illustrating the layout of pixels. FIG. 2H and FIG. 2I are diagrams each illustrating the structure of subpixels.

FIG. 3A is a diagram illustrating a display device. FIG. 3B and FIG. 3C are diagrams each illustrating the layout of pixels.

FIG. 4 is a cross-sectional view illustrating a display device.

FIG. 5A to FIG. 5C are cross-sectional views illustrating display devices.

FIG. 6A and FIG. 6B are cross-sectional views illustrating display devices.

FIG. 7A and FIG. 7B are cross-sectional views illustrating display devices.

FIG. 8A and FIG. 8B are cross-sectional views illustrating display devices.

FIG. 9 is a perspective view illustrating a display device.

FIG. 10 is a cross-sectional view illustrating a display device.

FIG. 11A and FIG. 11B are cross-sectional views illustrating a display device.

FIG. 12A and FIG. 12B are cross-sectional views illustrating a display device.

FIG. 13 is a cross-sectional view illustrating a display device.

FIG. 14A to FIG. 14D are diagrams illustrating circuits in a pixel.

FIG. 15 is a diagram illustrating circuits in a pixel.

FIG. 16 is a diagram illustrating circuits in a pixel.

FIG. 17A and FIG. 17B are diagrams illustrating an electronic device.

FIG. 18A to FIG. 18D are diagrams illustrating electronic devices.

FIG. 19A to FIG. 19F are diagrams illustrating electronic devices.

### MODE FOR CARRYING OUT THE INVENTION

Embodiments are described in detail with reference to the drawings. Note that the present invention is not limited to the following description, and it will be readily understood by those skilled in the art that modes and details of the present invention can be modified in various ways without departing from the spirit and scope. Therefore, the present invention should not be interpreted as being limited to the descriptions of embodiments below. Note that in structures of the invention described below, the same portions or portions having similar functions are denoted by the same reference numerals in different drawings, and the description thereof is not repeated in some cases. The same components are denoted by different hatching patterns in different drawings, or the hatching patterns are omitted in some cases.

Even in the case where a single component is illustrated in a circuit diagram, the component may be composed of a plurality of parts as long as there is no functional inconvenience. For example, in some cases, a plurality of transistors that operate as a switch are connected in series or in parallel. In some cases, capacitors are divided and arranged in a plurality of positions.

One conductor has a plurality of functions such as a wiring, an electrode, and a terminal in some cases. In this specification, a plurality of names are used for the same component in some cases. Even in the case where components are illustrated in a circuit diagram as if they were directly connected to each other, the components may actually be connected to each other through one or more conductors; in this specification, even such a structure is included in direct connection.

### Embodiment 1

In this embodiment, a display device of one embodiment of the present invention will be described.

One embodiment of the present invention is a display device that can perform an input operation even without contact. The display device includes a first light-emitting device, a second light-emitting device, and a light-receiving device. The first light-emitting device has a function of performing display, and the second light-emitting device has a function of emitting light that is to be applied to an object. The light-receiving device has a function of detecting light that has been emitted by the second light-emitting device and reflected by the object.

Near-infrared light, which has substantially no visibility, is used as the light emitted by the second light-emitting device. Therefore, the light emitted from a display portion even at high luminance does not affect visual recognition of the display. In addition, when the light is emitted at high luminance, an object that is positioned away from the display device can be detected with high sensitivity. The function makes it possible to achieve a near-touch sensor. The near-touch sensor is a sensor that achieves the same function as a touch sensor without contact.

A boosting circuit that is used for making the second light-emitting device emit light at high luminance is provided in a pixel including the second light-emitting device.

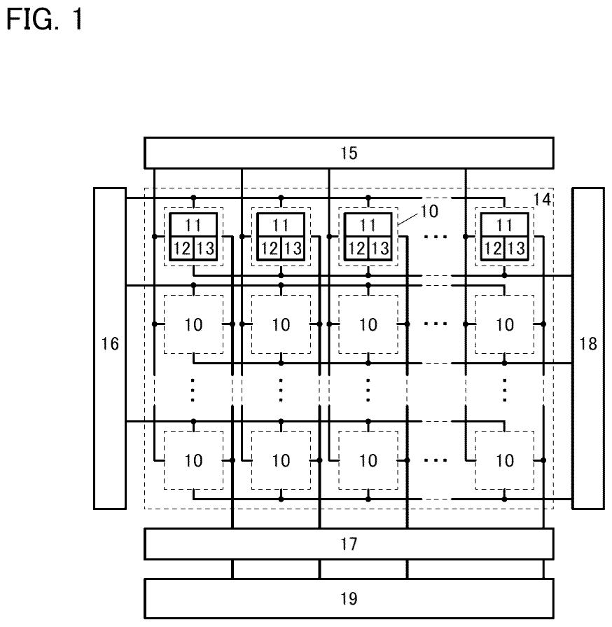

FIG. 1 is a diagram illustrating a display device of one embodiment of the present invention. The display device includes a pixel array 14, a circuit 15, a circuit 16, a circuit 17, a circuit 18, and a circuit 19. The pixel array 14 includes pixels 10 arranged in the column direction and the row direction.

The pixel 10 can include subpixels 11, 12, and 13. For example, the subpixel 11 has a function of emitting light for display. The subpixel 12 has a function of emitting light that is to be applied to an object. The subpixel 13 has a function of detecting light that has been emitted by the subpixel 12 and reflected by the object.

Note that in this specification, although a minimum unit in which an independent operation is performed in one “pixel” is defined as a “subpixel” in the following description for convenience, a “pixel” may be replaced with a “region” and a “subpixel” may be replaced with a “pixel”.

The subpixel 11 includes a first light-emitting device that emits visible light. The subpixel 12 includes a second light-emitting device that emits near-infrared light.

As the light-emitting devices, EL elements such as OLEDs (Organic Light Emitting Diodes) or QLEDs (Quantum-dot Light Emitting Diodes) are preferably used. Examples of a light-emitting substance included in the EL element include a substance emitting fluorescence (a fluorescent material), a substance emitting phosphorescence (a phosphorescent material), a substance exhibiting thermally activated delayed fluorescence (a thermally activated delayed fluorescent (TADF) material), and an inorganic compound (e.g., a quantum dot material). Alternatively, light-emitting diodes (LEDs) such as micro-LEDs can be used as the light-emitting devices.

The subpixel 13 includes a light-receiving device that has sensitivity to near-infrared light. A photoelectric conversion element that detects incident light and generates charge can be used as the light-receiving device. In the light-receiving device, the amount of charge to be generated is determined on the basis of the amount of incident light. For example, a pn or pin photodiode can be used as the light-receiving device.

It is preferable to use an organic photodiode including an organic compound in a photoelectric conversion layer, as the light-receiving device. An organic photodiode is easily made thin and lightweight and has a large area. In addition, an organic photodiode can be used in a variety of display devices because of its high flexibility in shape and design. Alternatively, a photodiode including crystalline silicon (e.g., single crystal silicon, polycrystalline silicon, or microcrystalline silicon) can be used as the light-receiving device.

In one embodiment of the present invention, organic EL elements are used as the light-emitting devices, and an organic photodiode is used as the light-receiving device. A large number of layers of the organic photodiode can be shared with the organic EL element. Accordingly, the light-receiving device can be incorporated into the display device without a significant increase in the number of manufacturing steps. For example, the photoelectric conversion layer of the light-receiving device and the light-emitting layers of the light-emitting devices may be separately formed, and the other layers may have the same structure for the light-emitting devices and the light-receiving device.

The circuit 15 and the circuit 16 are driver circuits for driving the subpixels 11 and 12. The circuit 15 can have a function of a source driver and the circuit 16 can have a function of a gate driver. A shift register circuit or the like can be used as the circuit 15 and the circuit 16, for example.

Note that the driver circuits for the subpixels 11 and 12 may be separated. A main function of the subpixel 12 is to irradiate an object with light; therefore, all the subpixels 12 in the pixel array 14 may emit light with the same luminance. Therefore, not high-performance sequential circuits or the like but simple circuits may be used as circuits corresponding to the source driver and the gate driver.

The circuit 17 and the circuit 18 are driver circuits for driving the subpixel 13. The circuit 17 can have a function of a column driver and the circuit 18 can have a function of a row driver. A shift register circuit, a decoder circuit, or the like can be used as the circuit 17 and the circuit 18, for example.

The circuit 19 is a reading circuit for data output from the subpixel 13. The circuit 19 includes, for example, an A/D converter circuit and has a function of converting analog data output from the subpixel 13 into digital data. In addition, the circuit 19 may include a CDS circuit that performs correlated double sampling processing on output data.

The subpixel 12 and the subpixel 13 can have a function of an input interface. Near-infrared light can be emitted from the subpixel 12, and reflection light from an object near the display device can be received by the subpixel 13. Thus, when a threshold value of the amount of received near-infrared light detected by the subpixel 13 is set, a function of a switch can be obtained. These make it possible to achieve a function equivalent to a touch sensor without contact. In addition, an operation of a pointer or the like can be performed with or without contact.

Imaging data on a fingerprint, a palm print, an iris, or the like can be obtained with the use of the light-receiving device. That is, a biological authentication function can be added to the display device. Note that imaging data may be obtained when an object is made to be in contact with the display device.

In addition, imaging data on facial expression, eye movement, change of the pupil diameter, or the like of the user can be obtained with the use of the light-receiving device. By analysis of the image data, information on the user's physical and mental state can be obtained. On the basis of the information, it is possible to perform an operation in accordance with the user's physical and mental state, e.g., to change one or both of display and sound output by the display device. Such operations are effective for devices for VR (Virtual Reality), devices for AR (Augmented Reality), or devices for MR (Mixed Reality).

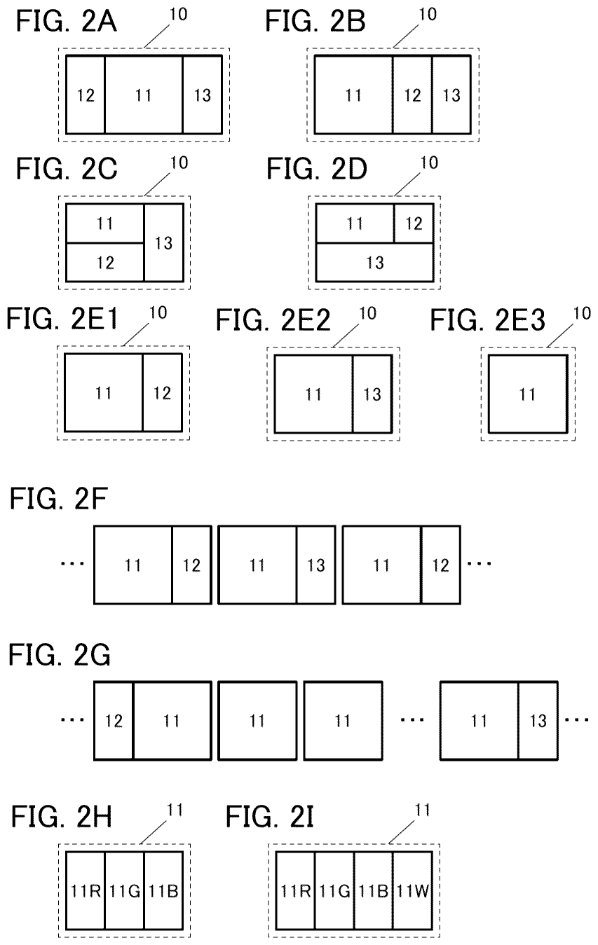

FIG. 2A to FIG. 2D and FIG. 2E1 to FIG. 2E3 are diagrams illustrating examples of the layout of the subpixels in the pixel 10. As illustrated in FIG. 2A and FIG. 2B, a structure in which the subpixels are arranged in a horizontal direction (a direction in which gate lines extend) can be employed. Alternatively, as illustrated in FIG. 1, FIG. 2C, and FIG. 2D, a structure in which the subpixels are arranged in the horizontal direction and a vertical direction (a direction in which source lines extend) may be employed.

Further alternatively, as illustrated in FIG. 2E1 and FIG. 2E2, a structure in which one pixel 10 does not include one of the subpixel 13 and the subpixel 12 may be employed. In this case, the pixel 10 in FIG. 2E1 and the pixel 10 in FIG. 2E2 can be alternately arranged as illustrated in FIG. 2F, for example. In addition, the pixel 10 illustrated in FIG. 2E3, which is formed only with the subpixel 11, may be used. In this case, as illustrated in FIG. 2G, a plurality of pixels 10 illustrated in FIG. 2E3 may be provided between the pixel 10 illustrated in FIG. 2E1 and the pixel 10 illustrated in FIG. 2E2. In the arrangements in FIG. 2F or FIG. 2G, the total number of subpixels 11 can be larger than the total number of subpixels 12 and 13, whereby the display quality can be increased.

By contrast, in the cases where the pixels 10 illustrated in FIG. 2E1 to FIG. 2E3 are used, the number of light sources for irradiating an object and the number of light-receiving devices are reduced, which results in a reduction in the sensitivity of detection for the object. Accordingly, the structure and arrangement of the subpixels are considered in accordance with the purpose. Note that the number of pixels 10 in FIG. 2E1 is not necessarily the same as the number of pixels 10 in FIG. 2E2 in the arrangement in FIG. 2F or FIG. 2G.

The subpixel 11 may be a group of subpixels that emit light of different colors as illustrated in FIG. 2H and FIG. 2I instead of having a structure that emits light of a single color. FIG. 2H illustrates an example in which the subpixel 11 is composed of a subpixel 11R that includes a red light-emitting device, a subpixel 11G that includes a green light-emitting device, and a subpixel 11B that includes a blue light-emitting device. Color display can be performed with the subpixels 11 having the above structure.

Furthermore, a subpixel 11W that includes a white light-emitting device may be provided as illustrated in FIG. 2I. Since the subpixel 11W can emit white light by itself, the emission luminance of subpixels of the other colors can be reduced in the case of display of white or a color close to white. Therefore, display can be performed with less power.

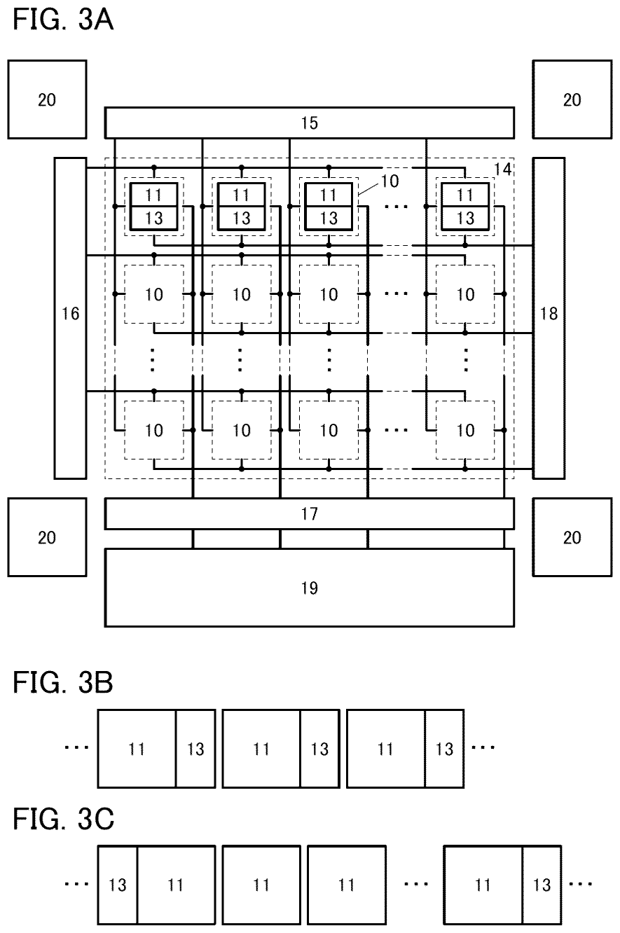

Alternatively, the display device may be configured such that the subpixel 11 and the subpixel 13 constitute the basic structure of the pixel 10 as illustrated in FIG. 3A. In this case, light sources 20 for irradiating the object are positioned outside the pixel array 14 (display portion). For example, LEDs that emit near-infrared light at high luminance can be used as the light sources 20. Since the light sources 20 are provided outside the pixel array 14, the light sources 20 can be turned on by a control separated from the display device. As in arrangement examples illustrated in FIG. 3B and FIG. 3C, the subpixel 12 is unnecessary and the number of subpixels 13 can be increased, so that the sensitivity of detection for an object can be increased.

Note that the positions and the number of light sources 20 illustrated in FIG. 3A are just an example and the positions and the number of light sources 20 are not limited thereto. The light source 20 can be one component of an apparatus that includes the display device of one embodiment of the present invention. Alternatively, the light source 20 may be an apparatus different from the apparatus including the display device of one embodiment of the present invention.

Note that the structures of the pixels and the subpixels are not limited to the above, and a variety of arrangement modes can be employed.

Next, a more specific example of the display device of one embodiment of the present invention is described below.

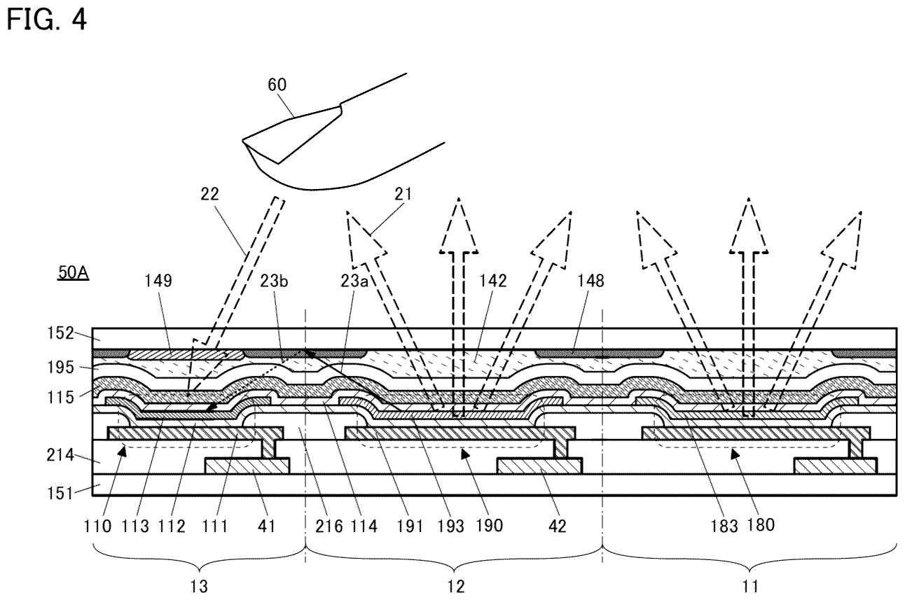

FIG. 4 is a cross-sectional schematic view of a display device 50A of one embodiment of the present invention. The display device 50A includes a light-receiving device 110, a light-emitting device 190, and a light-emitting device 180. The light-receiving device 110 corresponds to the organic photodiode included in the subpixel 13. The light-emitting device 190 corresponds to the organic EL element (emitting near-infrared light) included in the subpixel 12. The light-emitting device 180 corresponds to the organic EL element (emitting visible light) included in the subpixel 11.

The structures other than the light-emitting layer can be the same for the organic EL elements included in the subpixel 11 and the subpixel 12 and the periphery thereof. Therefore, the light-emitting device 190 will be described in detail here, and description of the light-emitting device 180 will be omitted.

The light-receiving device 110 includes a pixel electrode 111, a common layer 112, a photoelectric conversion layer 113, a common layer 114, and a common electrode 115. The light-emitting device 190 includes a pixel electrode 191, the common layer 112, a light-emitting layer 193, the common layer 114, and the common electrode 115. Note that the light-emitting device 180 includes a light-emitting layer 183 that is different from the light-emitting layer 193.

The pixel electrode 111, the pixel electrode 191, the common layer 112, the photoelectric conversion layer 113, the light-emitting layer 193, the common layer 114, and the common electrode 115 may each have a single-layer structure or a stacked-layer structure.

The pixel electrode 111 and the pixel electrode 191 are positioned over an insulating layer 214. The pixel electrode 111 and the pixel electrode 191 can be formed using the same material in the same step.

The common layer 112 is positioned over the pixel electrode 111 and the pixel electrode 191. The common layer 112 is shared by the light-receiving device 110 and the light-emitting device 190.

The photoelectric conversion layer 113 includes a region that overlaps with the pixel electrode 111 with the common layer 112 therebetween. The light-emitting layer 193 includes a region that overlaps with the pixel electrode 191 with the common layer 112 therebetween. The photoelectric conversion layer 113 includes a first organic compound. The light-emitting layer 193 includes a second organic compound different from the first organic compound.

The common layer 114 is positioned over the common layer 112, the photoelectric conversion layer 113, and the light-emitting layer 193. The common layer 114 is a layer shared by the light-receiving device 110 and the light-emitting device 190.

The common electrode 115 includes a region that overlaps with the pixel electrode 111 with the common layer 112, the photoelectric conversion layer 113, and the common layer 114 therebetween. The common electrode 115 further includes a region that overlaps with the pixel electrode 191 with the common layer 112, the light-emitting layer 193, and the common layer 114 therebetween. The common electrode 115 is a layer shared by the light-receiving device 110 and the light-emitting device 190.

In the display device of this embodiment, an organic compound is used for the photoelectric conversion layer 113 of the light-receiving device 110. In the light-receiving device 110, the layers other than the photoelectric conversion layer 113 can have structures in common with the layers in the light-emitting device 190 (the organic EL element). Therefore, the light-receiving device 110 can be formed concurrently with the formation of the light-emitting device 190 only by adding a step of depositing the photoelectric conversion layer 113 in the manufacturing process of the light-emitting device 190. The light-emitting device 190 and the light-receiving device 110 can be formed over one substrate. Accordingly, the light-receiving device 110 can be incorporated into the display device without a significant increase in the number of manufacturing steps.

In the display device 50A, the light-receiving device 110 and the light-emitting device 190 can have a common structure except that the photoelectric conversion layer 113 of the light-receiving device 110 and the light-emitting layer 193 of the light-emitting device 190 are separately formed. Note that the structures of the light-receiving device 110 and the light-emitting device 190 are not limited thereto. The light-receiving device 110 and the light-emitting device 190 may include a separately formed layer other than the photoelectric conversion layer 113 and the light-emitting layer 193 (see display devices 50C, 50D, and 50E described later). The light-receiving device 110 and the light-emitting device 190 preferably include one or more shared layers (common layer(s)). Thus, the light-receiving device 110 can be incorporated into the display device without a significant increase in the number of manufacturing steps.

The display device 50A includes the light-receiving device 110, the light-emitting device 190, a transistor 41, a transistor 42, and the like between a pair of substrates (a substrate 151 and a substrate 152).

In the light-receiving device 110, the common layer 112, the photoelectric conversion layer 113, and the common layer 114 that are positioned between the pixel electrode 111 and the common electrode 115 can each be referred to as an organic layer (a layer containing an organic compound). The pixel electrode 111 preferably has a function of reflecting near-infrared light. The common electrode 115 has a function of transmitting visible light and near-infrared light.

The light-receiving device 110 has a function of detecting light. Specifically, the light-receiving device 110 is a photoelectric conversion element that converts incident light 22 into an electric signal.

A light-blocking layer 148 is provided on a surface of the substrate 152 on the substrate 151 side. The light-blocking layer 148 has opening potions in a position overlapping with the light-receiving device 110 and in a position overlapping with the light-emitting device 190. Providing the light-blocking layer 148 can control the range where the light-receiving device 110 detects light.

A material that blocks light emitted by the light-emitting device 190 can be used for the light-blocking layer 148. The light-blocking layer 148 preferably absorbs visible light and near-infrared light. As the light-blocking layer 148, a black matrix can be formed using a metal material or a resin material containing pigment (e.g., carbon black) or dye, for example. The light-blocking layer 148 may have a stacked-layer structure of a red color filter, a green color filter, and a blue color filter.

A filter 149 that filters out light with wavelengths shorter than the wavelength of light (near-infrared light) emitted by the light-emitting device 190 is preferably provided in the opening portion of the light-blocking layer 148, which is provided in the position overlapping with the light-receiving device 110. For example, a longpass filter that filters out light having shorter wavelengths than near-infrared light, a bandpass filter that filters out at least wavelengths in the visible light region, or the like can be used as the filter 149. A resin film containing pigment or a semiconductor film such as an amorphous silicon thin film can be used as the filter that filters out visible light. When the filter 149 is provided, visible light can be inhibited from entering the light-receiving device 110, so that near-infrared light can be detected with less noise.

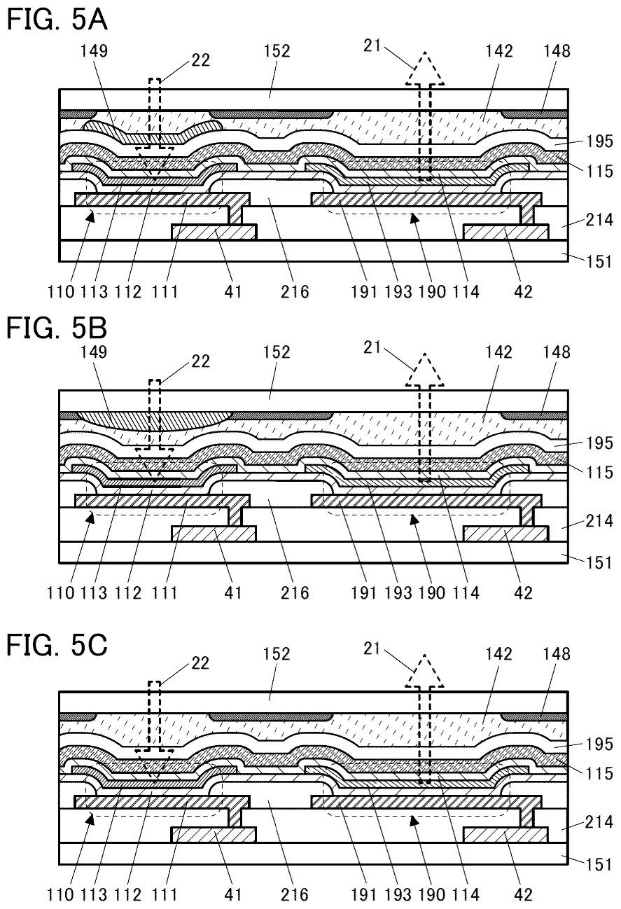

Note that the filter 149 may be provided to be stacked over the light-receiving device 110, as illustrated in FIG. 5A.

Alternatively, the filter 149 may have a lens shape as illustrated in FIG. 5B. The lens filter 149 is a convex lens having a convex surface on the substrate 151 side. Note that the filter 149 may be positioned so that the convex surface is on the substrate 152 side.

In the case where both the light-blocking layer 148 and the lens filter 149 are formed on the same surface of the substrate 152, their formation order is not limited. Although FIG. 5B illustrates an example in which the lens filter 149 is formed first, the light-blocking layer 148 may be formed first. In FIG. 5B, end portions of the lens filter 149 are covered with the light-blocking layer 148.

In the structure illustrated in FIG. 5B, the light 22 enters the light-receiving device 110 through the lens filter 149. When the filter 149 is a lens filter, the imaging range of the light-receiving device 110 can be narrowed to be inhibited from overlapping with the imaging range of an adjacent light-receiving device 110. Thus, a clear image with little blurring can be captured. In addition, when the filter 149 is a lens filter, the opening of the light-blocking layer 148 over the light-receiving device 110 can be large. Thus, the amount of light entering the light-receiving device 110 can be increased, so that light detection sensitivity can be increased.

The lens filter 149 can be directly formed on the substrate 152 or the light-receiving device 110. Alternatively, a separately formed microlens array or the like may be attached to the substrate 152.

A structure without the filter 149 may be employed as illustrated in FIG. 5C. The filter 149 can be omitted in the case where the light receiving device 110 has features such that it has no sensitivity to visible light or has sufficiently higher sensitivity to near-infrared light than that to visible light. In this case, a lens having a shape similar to that of the lens filter 149 in FIG. 5B may be provided to overlap with the light-receiving device 110. The lens may be formed using a material that transmits visible light.

Here, the light-receiving device 110 can detect the light 22 reflected by an object 60 such as a finger, of light 21 emitted by the light-emitting device 190, as illustrated in FIG. 4. However, in some cases, part of the light emitted by the light-emitting device 190 is reflected inside the display device 50A and enters the light-receiving device 110 without via the object 60.

The light-blocking layer 148 can reduce the influence of such stray light. For example, in the case where the light-blocking layer 148 is not provided, light 23a emitted by the light-emitting device 190 is reflected by the substrate 152 or the like and reflected light 23b enters the light-receiving device 110 in some cases. Providing the light-blocking layer 148 can inhibit entry of the reflected light 23b into the light-receiving device 110. Hence, noise can be reduced and the accuracy of light detection of the light-receiving device 110 can be increased.

In the light-emitting device 190, the common layer 112, the light-emitting layer 193, and the common layer 114 that are positioned between the pixel electrode 191 and the common electrode 115 can each be referred to as an EL layer. The pixel electrode 191 preferably has a function of reflecting at least near-infrared light.

The light-emitting device 190 has a function of emitting near-infrared light. Specifically, the light-emitting device 190 is an electroluminescent device that emits the light 21 to the substrate 152 side by application of voltage between the pixel electrode 191 and the common electrode 115.

The pixel electrode 111 is electrically connected to a source or a drain of the transistor 41 through an opening provided in the insulating layer 214. An end portion of the pixel electrode 111 is covered with a partition 216.

The pixel electrode 191 is electrically connected to a source or a drain of the transistor 42 through an opening provided in the insulating layer 214. An end portion of the pixel electrode 191 is covered with the partition 216. The transistor 42 has a function of controlling the driving of the light-emitting device 190.

The transistor 41 and the transistor 42 are on and in contact with the same layer (the substrate 151 in FIG. 4).

At least part of a circuit electrically connected to the light-receiving device 110 is preferably formed using the same material in the same steps as a circuit electrically connected to the light-emitting device 190. Accordingly, the thickness of the display device can be smaller and the manufacturing process can be simpler than those in the case where the two circuits are separately formed.

The light-receiving device 110 and the light-emitting device 190 are preferably covered with a protective layer 195. In FIG. 4, the protective layer 195 is provided on and in contact with the common electrode 115, for example. Providing the protective layer 195 can inhibit entry of impurities such as water into the light-receiving device 110 and the light-emitting device 190, thereby increasing the reliability of the light-receiving device 110 and the light-emitting device 190. The protective layer 195 and the substrate 152 are bonded to each other with an adhesive layer 142.

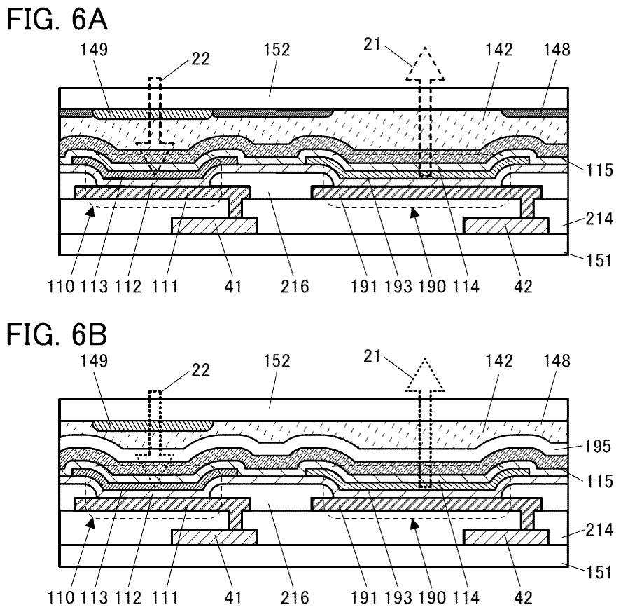

A structure in which no protective layer 195 is provided over the light-receiving device 110 and the light-emitting device 190 may be employed as illustrated in FIG. 6A. In this case, the common electrode 115 and the substrate 152 are attached to each other with the adhesive layer 142.

A structure without the light-blocking layer 148 may be employed as illustrated in FIG. 6B. Thus, the amount of light which the light-emitting device 190 emits to the outside and the amount of light received by the light-receiving device 110 can be increased, so that the detection sensitivity can be increased.

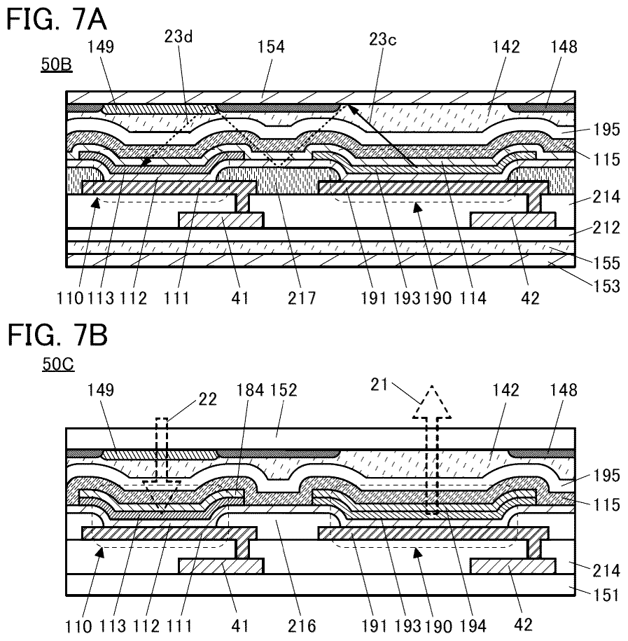

The display device of one embodiment of the present invention may have a structure of a display device 50B illustrated in FIG. 7A. The display device 50B differs from the display device 50A in that the substrate 151, the substrate 152, and the partition 216 are not included and a substrate 153, a substrate 154, an adhesive layer 155, an insulating layer 212, and a partition 217 are included.

The substrate 153 and the insulating layer 212 are bonded to each other with the adhesive layer 155. The substrate 154 and the protective layer 195 are bonded to each other with the adhesive layer 142.

The display device 50B has a structure formed in such a manner that the insulating layer 212, the transistor 41, the transistor 42, the light-receiving device 110, the light-emitting device 190, and the like that are formed over a formation substrate are transferred onto the substrate 153. The substrate 153 and the substrate 154 are preferably flexible. Accordingly, flexibility can be imparted to the display device 50B. For example, a resin is preferably used for the substrate 153 and the substrate 154.

For the substrate 153 and the substrate 154, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for one or both of the substrate 153 and the substrate 154.

As the substrate included in the display device of this embodiment, a film having high optical isotropy may be used. Examples of the film having high optical isotropy include a triacetyl cellulose (TAC, also referred to as cellulose triacetate) film, a cycloolefin polymer (COP) film, a cycloolefin copolymer (COC) film, and an acrylic film.

The partition 217 is preferably capable of absorbing light emitted by the light-emitting device 190. The partition 217 can be formed using, for example, a metal material, a resin material containing a pigment or dye, or the like.

Part of light 23c emitted by the light-emitting device 190 is reflected by the substrate 152 and the partition 217. The reflected light 23d sometimes enters the light-receiving device 110. Furthermore, the light 23c sometimes passes through the partition 217 and is reflected by a transistor, a wiring, or the like, and thus reflected light can enter the light-receiving device 110. When the partition 217 absorbs the light 23c, the reflected light 23d can be inhibited from entering the light-receiving device 110. Hence, noise can be reduced, and the accuracy of light detection of the light-receiving device 110 can be increased.

The partition 217 preferably absorbs at least light with a wavelength that can be detected by the light-receiving device 110. For example, in the case where the light-receiving device 110 detects near-infrared light emitted by the light-emitting device 190, it is preferable that the partition 217 can absorb at least near-infrared light and can absorb visible light.

Although the light-emitting device and the light-receiving device include two common layers in the above, one embodiment of the present invention is not limited thereto. Examples in which common layers have different structures are described below.

FIG. 7B is a schematic cross-sectional view of a display device 50C. The display device 50C differs from the display device 50A in that the common layer 114 is not included and a buffer layer 184 and a buffer layer 194 are included. The buffer layer 184 and the buffer layer 194 may each have a single-layer structure or a stacked-layer structure.

In the display device 50C, the light-receiving device 110 includes the pixel electrode 111, the common layer 112, the photoelectric conversion layer 113, the buffer layer 184, and the common electrode 115. In the display device 50C, the light-emitting device 190 includes the pixel electrode 191, the common layer 112, the light-emitting layer 193, the buffer layer 194, and the common electrode 115.

In the display device 50C, an example is shown in which the buffer layer 184 between the common electrode 115 and the photoelectric conversion layer 113 and the buffer layer 194 between the common electrode 115 and the light-emitting layer 193 are formed separately. As each of the buffer layer 184 and the buffer layer 194, one or both of an electron-injection layer and an electron-transport layer can be formed, for example.

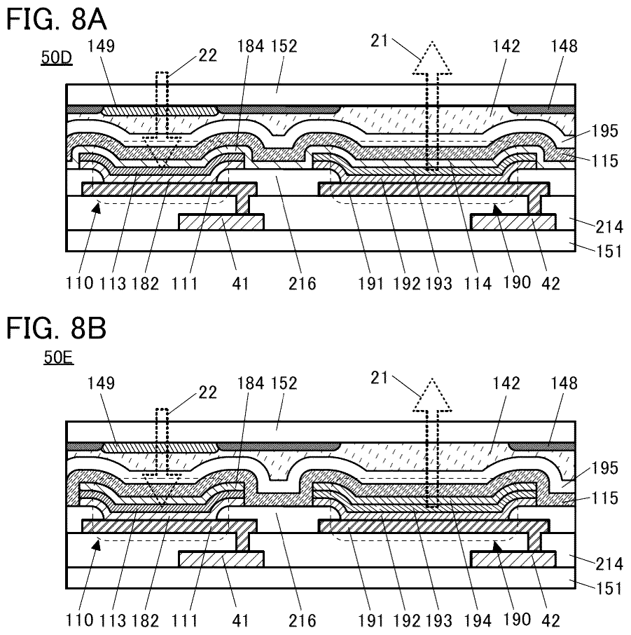

FIG. 8A is a schematic cross-sectional view of a display device 50D. The display device 50D differs from the display device 50A in that the common layer 112 is not included and a buffer layer 182 and a buffer layer 192 are included. The buffer layer 182 and the buffer layer 192 may each have a single-layer structure or a stacked-layer structure.

In the display device 50D, the light-receiving device 110 includes the pixel electrode 111, the buffer layer 182, the photoelectric conversion layer 113, the common layer 114, and the common electrode 115. In the display device 50D, the light-emitting device 190 includes the pixel electrode 191, the buffer layer 192, the light-emitting layer 193, the common layer 114, and the common electrode 115.

In the display device 50D, an example is shown in which the buffer layer 182 between the pixel electrode 111 and the photoelectric conversion layer 113 and the buffer layer 192 between the pixel electrode 191 and the light-emitting layer 193 are formed separately. As each of the buffer layer 182 and the buffer layer 192, one or both of a hole-injection layer and a hole-transport layer can be formed, for example.

FIG. 8B is a schematic cross-sectional view of a display device 50E. The display device 50E differs from the display device 50A in that the common layer 112 and the common layer 114 are not included and the buffer layer 182, the buffer layer 184, the buffer layer 192, and the buffer layer 194 are included.

In the display device 50E, the light-receiving device 110 includes the pixel electrode 111, the buffer layer 182, the photoelectric conversion layer 113, the buffer layer 184, and the common electrode 115. In the display device 50E, the light-emitting device 190 includes the pixel electrode 191, the buffer layer 192, the light-emitting layer 193, the buffer layer 194, and the common electrode 115.

Other layers as well as the photoelectric conversion layer 113 and the light-emitting layer 193 can be formed separately in the manufacturing process of the light-receiving device 110 and the light-emitting device 190.

An example is shown in which the light-receiving device 110 and the light-emitting device 190 do not have a common layer between the pair of electrodes (the pixel electrode 111 or the pixel electrode 191 and the common electrode 115) in the display device 50E. In the manufacturing process of the light-receiving device 110 and the light-emitting device 190 included in the display device 50E, first, the pixel electrode 111 and the pixel electrode 191 are formed over the insulating layer 214 using the same material in the same step. Then, the buffer layer 182, the photoelectric conversion layer 113, and the buffer layer 184 are formed over the pixel electrode 111; the buffer layer 192, the light-emitting layer 193, and the buffer layer 194 are formed over the pixel electrode 191; and the common electrode 115 is formed so as to cover the buffer layer 184, the buffer layer 194, and the like.

Note that the manufacturing order of the stacked-layer structure of the buffer layer 182, the photoelectric conversion layer 113, and the buffer layer 184 and the stacked-layer structure of the buffer layer 192, the light-emitting layer 193, and the buffer layer 194 is not particularly limited. For example, after the buffer layer 182, the photoelectric conversion layer 113, and the buffer layer 184 are deposited, the buffer layer 192, the light-emitting layer 193, and the buffer layer 194 may be formed. In contrast, the buffer layer 192, the light-emitting layer 193, and the buffer layer 194 may be formed before the buffer layer 182, the photoelectric conversion layer 113, and the buffer layer 184 are deposited. Alternatively, alternate deposition of the buffer layer 182, the buffer layer 192, the photoelectric conversion layer 113, and the light-emitting layer 193 in this order may be performed.

Next, a more specific structure example of the display device of one embodiment of the present invention will be described below.

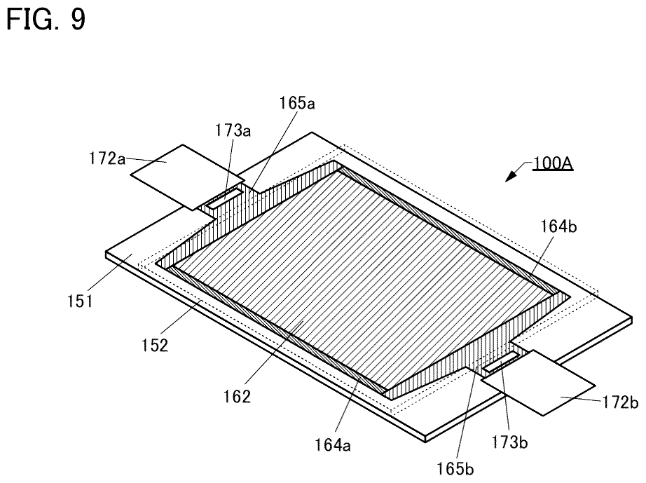

FIG. 9 illustrates a perspective view of a display device 100A. The display device 100A has a structure in which the substrate 151 and the substrate 152 are bonded to each other. In FIG. 9, the substrate 152 is denoted by a dashed line.

The display device 100A includes a display portion 162, a circuit 164a, a circuit 164b, a wiring 165a, a wiring 165b, and the like. FIG. 9 illustrates an example in which an IC (integrated circuit) 173a, an FPC 172a, an IC 173b, and an FPC 172b are mounted on the display device 100A. Therefore, the structure illustrated in FIG. 9 can be regarded as a display module including the display device 100A, the ICs, and the FPCs.

A gate driver for performing display can be used as the circuit 164a. A row driver for performing imaging (light detection) can be used as the circuit 164b.

The wiring 165a has a function of supplying a signal and power to the subpixels 11 and 12 and the circuit 164a. The signal and the power are input to the wiring 165a from the outside through the FPC 172a or input to the wiring 165a from the IC 173a.

The wiring 165b has a function of supplying a signal and power to the subpixel 13 and the circuit 164b. The signal and the power are input to the wiring 165b from the outside through the FPC 172b or input to the wiring 165b from the IC 173b.

Although FIG. 9 illustrates an example in which the ICs 173a and 173b are provided on the substrate 151 by a COG (Chip On Glass) method, a TCP (Tape Carrier Package) method, a COF (Chip On Film) method, or the like may be used. An IC having a function of a source driver connected to the subpixels 11 and 12 can be used as the IC 173a, for example. An IC having functions of a column driver connected to the subpixel 13 and a signal processing circuit such as an A/D converter can be used as the IC 173b, for example.

Note that the driver circuits may be provided over the substrate 151 as well as the transistor included in the circuit of the pixel and the like.

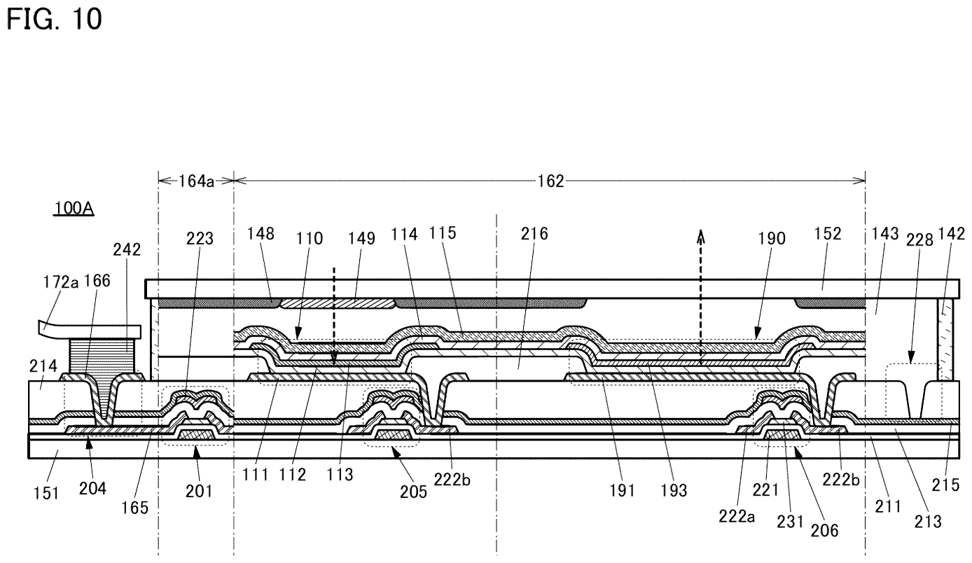

FIG. 10 illustrates an example of cross sections of part of a region including the FPC 172a, part of a region including the circuit 164a, part of a region including the display portion 162, and part of a region including an end portion in the display device 100A illustrated in FIG. 9.

The display device 100A illustrated in FIG. 10 includes a transistor 201, a transistor 205, a transistor 206, the light-emitting device 190, the light-receiving device 110, and the like between the substrate 151 and the substrate 152.

The substrate 152 and the insulating layer 214 are bonded to each other with the adhesive layer 142. A solid sealing structure, a hollow sealing structure, or the like can be employed to seal the light-emitting device 190 and the light-receiving device 110. A hollow sealing structure is employed in which a space 143 surrounded by the substrate 152, the adhesive layer 142, and the insulating layer 214 is filled with an inert gas (e.g., nitrogen or argon). The adhesive layer 142 may be provided to overlap with the light-emitting device 190. The region surrounded by the substrate 152, the adhesive layer 142, and the insulating layer 214 may be filled with a resin different from that of the adhesive layer 142.

The light-emitting device 190 has a stacked-layer structure in which the pixel electrode 191, the common layer 112, the light-emitting layer 193, the common layer 114, and the common electrode 115 are stacked in this order from the insulating layer 214 side. The pixel electrode 191 is connected to a conductive layer 222b included in the transistor 206 through an opening provided in the insulating layer 214. The transistor 206 has a function of controlling the driving of the light-emitting device 190. An end portion of the pixel electrode 191 is covered with the partition 216.

The light-receiving device 110 has a stacked-layer structure in which the pixel electrode 111, the common layer 112, the photoelectric conversion layer 113, the common layer 114, and the common electrode 115 are stacked in that order from the insulating layer 214 side. The pixel electrode 111 is electrically connected to the conductive layer 222b included in the transistor 205 through an opening provided in the insulating layer 214. An end portion of the pixel electrode 111 is covered with the partition 216.

Light emitted by the light-emitting device 190 is emitted to the substrate 152 side. Light enters the light-receiving device 110 through the substrate 152 and the space 143. For the substrate 152, a material having a high transmitting property with respect to visible light and near-infrared light is preferably used.

The pixel electrode 111 and the pixel electrode 191 can be formed using the same material in the same step. The common layer 112, the common layer 114, and the common electrode 115 are used in both the light-receiving device 110 and the light-emitting device 190. The light-receiving device 110 and the light-emitting device 190 can have common structures except the photoelectric conversion layer 113 and the light-emitting layer 193. Thus, the light-receiving device 110 can be incorporated into the display device 100A without a significant increase in the number of manufacturing steps.

The light-blocking layer 148 is provided on a surface of the substrate 152 on the substrate 151 side. The light-blocking layer 148 has openings in a position overlapping with the light-receiving device 110 and in a position overlapping with the light-emitting device 190. The filter 149 that filters out visible light is provided in a position overlapping with the light-receiving device 110. Note that a structure without the filter 149 can be employed.

The transistor 201, the transistor 205, and the transistor 206 are formed over the substrate 151. These transistors can be manufactured using the same materials in the same process.

An insulating layer 211, an insulating layer 213, an insulating layer 215, and the insulating layer 214 are provided in this order over the substrate 151. Parts of the insulating layer 211 function as gate insulating layers of the transistors. Parts of the insulating layer 213 function as gate insulating layers of the transistors. The insulating layer 215 is provided to cover the transistors. The insulating layer 214 is provided to cover the transistors and has a function of a planarization layer. Note that the number of gate insulating layers and the number of insulating layers covering the transistors are not limited, and a single layer or two or more layers may be employed.

A material through which impurities such as water and hydrogen do not easily diffuse is preferably used for at least one of the insulating layers that cover the transistors. Thus, such an insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used. Alternatively, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used. A stack including two or more of the above insulating films may also be used.

An organic insulating film is suitable for the insulating layer 214 functioning as a planarization layer. Examples of materials which can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Here, an organic insulating film often has a lower barrier property against impurities than an inorganic insulating film. Therefore, the organic insulating film preferably has an opening in the vicinity of an end portion of the display device 100A. This can inhibit diffusion of impurities from the end portion of the display device 100A through the organic insulating film. Alternatively, the organic insulating film may be formed so that an end portion of the organic insulating film is positioned on the inner side compared to the end portion of the display device 100A, to prevent the organic insulating film from being exposed at the end portion of the display device 100A.

In a region 228 illustrated in FIG. 10, an opening is formed in the insulating layer 214. This can inhibit diffusion of impurities into the display portion 162 from the outside through the insulating layer 214 even when an organic insulating film is used as the insulating layer 214. Thus, the reliability of the display device 100A can be increased.

The transistor 201, the transistor 205, and the transistor 206 each include a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, or an inverted staggered transistor can be used. A top-gate or bottom-gate transistor structure may be employed. Alternatively, gates may be provided above and below a semiconductor layer where a channel is formed.

A structure in which the semiconductor layer where a channel is formed is sandwiched between the two gates is used for the transistor 201, the transistor 205, and the transistor 206. The two gates may be connected to each other and supplied with the same signal to operate the transistor. Alternatively, one of the two gates may be supplied with a potential for controlling the threshold voltage of the transistor and the other may be supplied with a potential for driving.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable that a single crystal semiconductor or a semiconductor having crystallinity be used, in which case deterioration of the transistor characteristics can be inhibited.

It is preferable that a semiconductor layer of a transistor contain a metal oxide (also referred to as an oxide semiconductor). Alternatively, the semiconductor layer of the transistor may contain silicon. Examples of silicon include amorphous silicon and crystalline silicon (e.g., low-temperature polysilicon or single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable to use an oxide containing indium (In), gallium (Ga), and zinc (Zn) (also referred to as IGZO) for the semiconductor layer.

In the case where an In—M—Zn oxide is deposited by a sputtering method, the atomic proportion of In is preferably higher than or equal to the atomic proportion of M in a sputtering target. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:6, In:M:Zn=5:1:7, In:M:Zn=5:1:8, In:M:Zn=6:1:6, and In:M:Zn=5:2:5.

A target containing a polycrystalline oxide is preferably used as the sputtering target, in which case the semiconductor layer having crystallinity is easily formed. Note that the atomic ratio in the deposited semiconductor layer may vary from the above atomic ratio between metal elements in the sputtering target in a range of ±40%. For example, in the case where the composition of a sputtering target used for the semiconductor layer is In:Ga:Zn=4:2:4.1 [atomic ratio], the composition of the semiconductor layer to be deposited is in some cases in the neighborhood of In:Ga:Zn=4:2:3 [atomic ratio].

Note that when the atomic ratio is described as In:Ga:Zn=4:2:3 or as being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. When the atomic ratio is described as In:Ga:Zn=5:1:6 or as being in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. When the atomic ratio is described as In:Ga:Zn=1:1:1 or as being in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The transistors included in the circuit 164a and the transistors included in the display portion 162 may have the same structure or different structures. One structure or two or more kinds of structures may be employed for the plurality of transistors included in the circuit 164a. Similarly, one structure or two or more kinds of structures may be employed for a plurality of transistors included in the display portion 162.

A connection portion 204 is provided in a region that is over the substrate 151 and does not overlap with the substrate 152. In the connection portion 204, the wiring 165 is electrically connected to the FPC 172a through a conductive layer 166 and a connection layer 242. On a top surface of the connection portion 204, the conductive layer 166 obtained by processing the same conductive film as the pixel electrode 191 is exposed. Thus, the connection portion 204 and the FPC 172a can be electrically connected to each other through the connection layer 242.

Any of a variety of optical members can be arranged on the outer side of the substrate 152. Examples of the optical members include a polarizing plate, a retardation plate, a light diffusion layer (a diffusion film or the like), an anti-reflective layer, and a light-condensing film. Furthermore, an antistatic film preventing the attachment of dust, a water repellent film suppressing the attachment of stain, a hard coat film inhibiting generation of a scratch caused by the use, a shock absorption layer, or the like may be arranged on the outside of the substrate 152.

Glass, quartz, ceramic, sapphire, a resin, or the like can be used for the substrate 151 and the substrate 152

As the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. An adhesive sheet or the like may be used.

As the connection layer 242, an anisotropic conductive film (ACF), an anisotropic conductive paste (ACP), or the like can be used.

The light-emitting device 190 may be of a top emission type, a bottom emission type, a dual emission type, or the like. Although the light-emitting device 190 is preferably of a top emission type in one embodiment of the present invention, another structure can be used when a light-emitting surface of the light-emitting device 190 and a light incident surface of the light-receiving device 110 face in the same direction.

The light-emitting device 190 includes at least the light-emitting layer 193. In addition to the light-emitting layer 193, the light-emitting device 190 may further include a layer containing a substance with a high hole-injection property, a substance with a high hole-transport property, a hole-blocking material, a substance with a high electron-transport property, a substance with a high electron-injection property, a substance with a bipolar property (a substance with a high electron-and hole-transport property), or the like. For example, the common layer 112 preferably includes one or both of a hole-injection layer and a hole-transport layer. For example, the common layer 114 preferably includes one or both of an electron-transport layer and an electron-injection layer.

Either a low molecular compound or a high molecular compound can be used for the common layer 112, the light-emitting layer 193, and the common layer 114, and an inorganic compound may be contained. The layers included in the common layer 112, the light-emitting layer 193, and the common layer 114 can be formed by a method such as an evaporation method (including a vacuum evaporation method), a transfer method, a printing method, an inkjet method, or a coating method.

The light-emitting layer 193 may contain an inorganic compound such as quantum dots as a light-emitting material.

The photoelectric conversion layer 113 of the light-receiving device 110 contains a semiconductor. As the semiconductor, an inorganic semiconductor such as silicon or an organic semiconductor containing an organic compound can be used. This embodiment shows an example in which an organic semiconductor is used as the semiconductor included in the photoelectric conversion layer 113. The use of an organic semiconductor is preferable because the light-emitting layer 193 of the light-emitting device 190 and the photoelectric conversion layer 113 of the light-receiving device 110 can be formed by the same method (e.g., a vacuum evaporation method) and thus the same manufacturing apparatus can be used.

Examples of an n-type semiconductor material included in the photoelectric conversion layer 113 are electron-accepting organic semiconductor materials such as fullerene (e.g., C₆₀ and C₇₀) and derivatives thereof. As a p-type semiconductor material included in the photoelectric conversion layer 113, an electron-donating organic semiconductor material such as copper(II) phthalocyanine (CuPc), tetraphenyldibenzoperiflanthene (DBP), or zinc phthalocyanine (ZnPc) can be given.

For example, the photoelectric conversion layer 113 is preferably formed by co-evaporation of an n-type semiconductor and a p-type semiconductor.

As materials that can be used for conductive layers such as a variety of wirings and electrodes that constitute a display device, in addition to a gate, a source, and a drain of a transistor, metals such as aluminum, titanium, chromium, nickel, copper, yttrium, zirconium, molybdenum, silver, tantalum, or tungsten, or an alloy containing any of these metals as its main component can be given. A film containing any of these materials can be used as a single-layer structure or a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), the thickness is preferably set small enough to be able to transmit light. A stacked-layer film of any of the above materials can be used for the conductive layers. For example, when a stacked film of indium tin oxide and an alloy of silver and magnesium, or the like is used, the conductivity can be increased, which is preferable. They can also be used for conductive layers such as a variety of wirings and electrodes that constitute a display device, and conductive layers (conductive layers functioning as a pixel electrode or a common electrode) included in a display element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

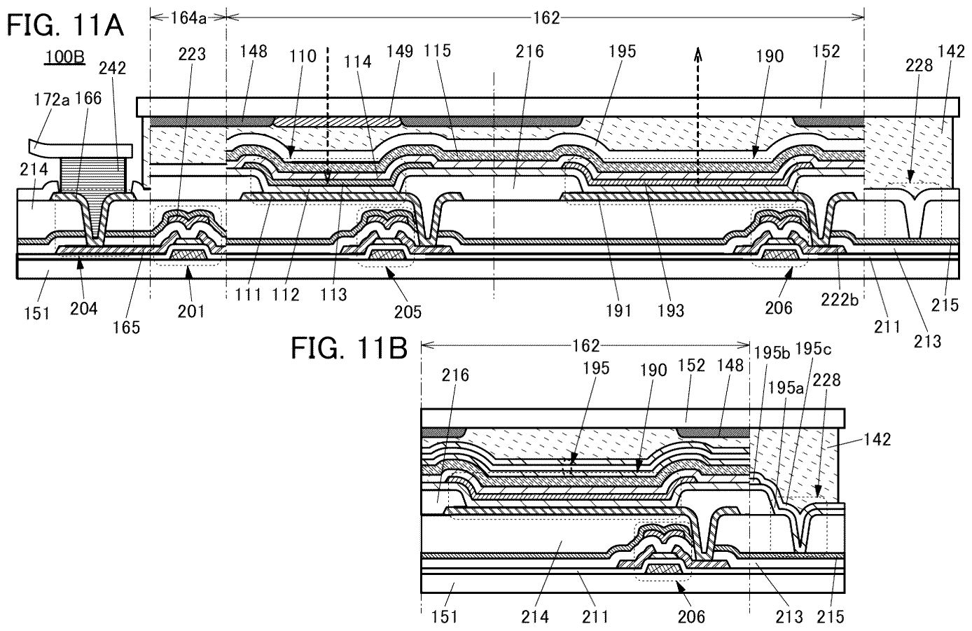

FIG. 11A illustrates a cross-sectional view of a display device 100B. The display device 100B differs from the display device 100A mainly in that the protective layer 195 is included.

Providing the protective layer 195 that covers the light-receiving device 110 and the light-emitting device 190 can inhibit diffusion of impurities such as water into the light-receiving device 110 and the light-emitting device 190, thereby increasing the reliability of the light-receiving device 110 and the light-emitting device 190.

In the region 228 in the vicinity of an end portion of the display device 100B, the insulating layer 215 and the protective layer 195 are preferably in contact with each other through an opening in the insulating layer 214. In particular, the inorganic insulating film included in the insulating layer 215 and the inorganic insulating film included in the protective layer 195 are preferably in contact with each other. Thus, diffusion of impurities from the outside into the display portion 162 through the organic insulating film can be inhibited. Thus, the reliability of the display device 100B can be increased.

FIG. 11B illustrates an example in which the protective layer 195 has a three-layer structure. The protective layer 195 includes an inorganic insulating layer 195a over the common electrode 115, an organic insulating layer 195b over the inorganic insulating layer 195a, and an inorganic insulating layer 195c over the organic insulating layer 195b.

An end portion of the inorganic insulating layer 195a and an end portion of the inorganic insulating layer 195c extend beyond an end portion of the organic insulating layer 195b and are in contact with each other. The inorganic insulating layer 195a is in contact with the insulating layer 215 (inorganic insulating layer) through the opening in the insulating layer 214 (organic insulating layer). Accordingly, the light-receiving device 110 and the light-emitting device 190 can be surrounded by the insulating layer 215 and the protective layer 195, whereby the reliability of the light-receiving device 110 and the light-emitting device 190 can be increased.

As described above, the protective layer 195 may have a stacked-layer structure of an organic insulating film and an inorganic insulating film. In that case, an end portion of the inorganic insulating film preferably extends beyond an end portion of the organic insulating film.

In the display device 100B, the protective layer 195 and the substrate 152 are bonded to each other with the adhesive layer 142. The adhesive layer 142 is provided to overlap with the light-receiving device 110 and the light-emitting device 190; that is, the display device 100B employs a solid sealing structure.

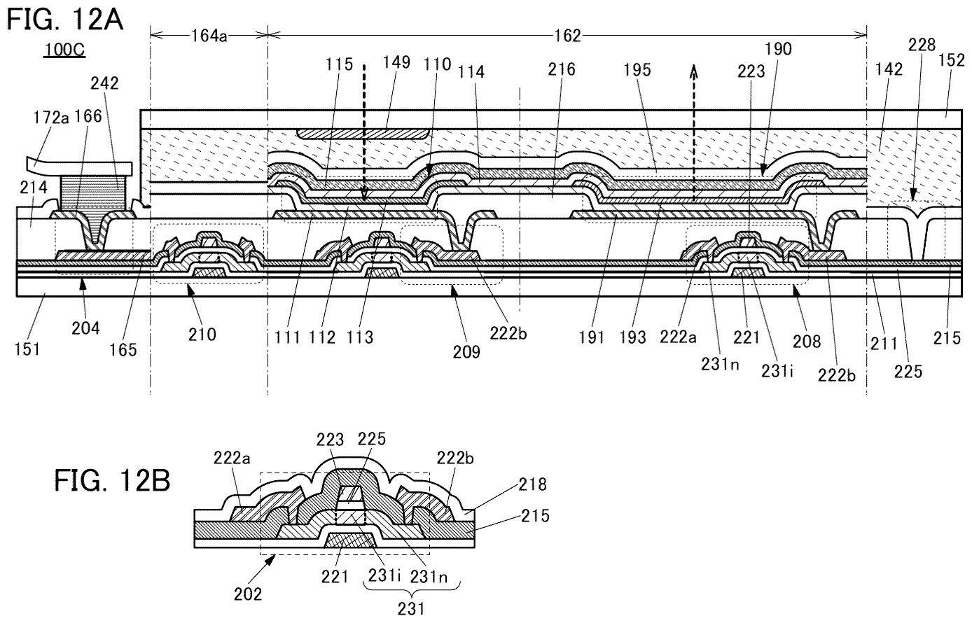

FIG. 12A illustrates a cross-sectional view of a display device 100C. The display device 100C differs from the display device 100B mainly in the structure of transistors and in not including the light-blocking layer 148.

The display device 100C includes a transistor 208, a transistor 209, and a transistor 210 over the substrate 151.

The transistor 208, the transistor 209, and the transistor 210 each include the conductive layer 221 functioning as a gate, the insulating layer 211 functioning as a gate insulating layer, a semiconductor layer including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the respective low-resistance regions 231n through openings provided in the insulating layer 225 and the insulating layer 215. One of the conductive layer 222a and the conductive layer 222b functions as a source and the other functions as a drain.

The pixel electrode 191 of the light-emitting device 190 is electrically connected to one of the pair of low-resistance regions 231n of the transistor 208 through the conductive layer 222b.

The pixel electrode 111 of the light-receiving device 110 is electrically connected to the other of the pair of low-resistance regions 231n of the transistor 209 through the conductive layer 222b.

FIG. 12A illustrates an example in which the insulating layer 225 covers a top surface and a side surface of the semiconductor layer. FIG. 12B illustrates an example in which the insulating layer 225 overlaps with the channel formation region 231i of the semiconductor layer 231 and does not overlap with the low-resistance regions 231n. The structure illustrated in FIG. 12B can be manufactured by processing the insulating layer 225 using the conductive layer 223 as a mask, for example. In FIG. 12B, the insulating layer 215 is provided to cover the insulating layer 225 and the conductive layer 223, and the conductive layer 222a and the conductive layer 222b are connected to the low-resistance regions 231n through openings in the insulating layer 215. Furthermore, an insulating layer 218 covering the transistor may be provided.

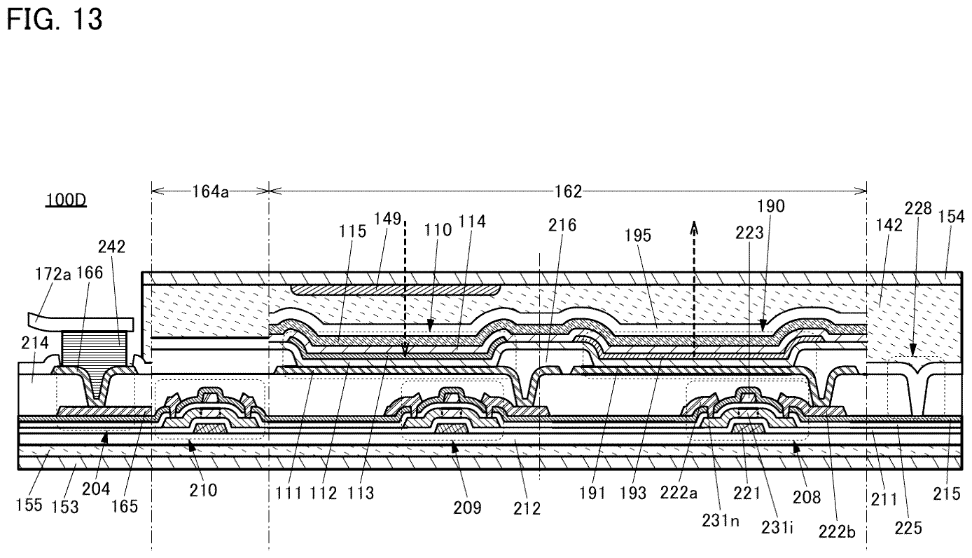

FIG. 13 illustrates a cross-sectional view of a display device 100D. The display device 100D differs from the display device 100C mainly in the structure of the substrate.

The display device 100D does not include the substrate 151 and the substrate 152 and includes the substrate 153, the substrate 154, the adhesive layer 155, and the insulating layer 212.

The substrate 153 and the insulating layer 212 are bonded to each other with the adhesive layer 155. The substrate 154 and the protective layer 195 are bonded to each other with the adhesive layer 142.

The display device 100D is formed in such a manner that the insulating layer 212, the transistor 208, the transistor 209, the light-receiving device 110, the light-emitting device 190, and the like that are formed over a formation substrate are transferred onto the substrate 153. The substrate 153 and the substrate 154 are preferably flexible. Accordingly, flexibility can be imparted to the display device 100D.

The inorganic insulating film that can be used as the insulating layer 211, the insulating layer 213, and the insulating layer 215 can be used as the insulating layer 212. Alternatively, a stacked film of an organic insulating film and an inorganic insulating film may be used as the insulating layer 212. At this time, a film on the transistor 209 side is preferably an inorganic insulating film.

The above is the description of the structure example of the display device.

The display device of this embodiment includes a light-receiving device and a light-emitting device in a display portion, and the display portion has both a function of displaying an image and a function of detecting light. Thus, the size and weight of an electronic device can be reduced as compared to the case where a sensor is provided outside a display portion or outside a display device. Moreover, an electronic device having more functions can be obtained by a combination of the display device of this embodiment and a sensor provided outside the display portion or outside the display device.

In the light-receiving device, at least one layer other than the photoelectric conversion layer can have a structure in common with the layer in the light-emitting device (the EL element). Furthermore, in the light-receiving device, all the layers other than the photoelectric conversion layer can have structures in common with the layers in the light-emitting device (EL element). With only the addition of the step of depositing the photoelectric conversion layer to the manufacturing process of the light-emitting device, the light-emitting device and the light-receiving device can be formed over one substrate, for example. In the light-receiving device and the light-emitting device, the pixel electrodes and the common electrode can be formed using the same material in the same step. When a circuit electrically connected to the light-receiving device and a circuit electrically connected to the light-emitting device are formed using the same material in the same process, the manufacturing process of the display device can be simplified. In such a manner, a display device that incorporates a light-receiving device and is highly convenient can be manufactured without complicated steps.

A metal oxide that can be used in the semiconductor layer of the transistor will be described below.

Note that in this specification and the like, a metal oxide containing nitrogen is also referred to as a metal oxide in some cases. A metal oxide containing nitrogen may be referred to as a metal oxynitride. For example, a metal oxide containing nitrogen, such as zinc oxynitride (ZnON), may be used for the semiconductor layer.

Note that in this specification and the like, CAAC (c-axis aligned crystal) and CAC (Cloud-Aligned Composite) are sometimes stated. Note that CAAC refers to an example of a crystal structure, and CAC refers to an example of a function or a material composition.

For example, a CAC (Cloud-Aligned Composite)-OS (Oxide Semiconductor) can be used for the semiconductor layer.

A CAC-OS or a CAC-metal oxide has a conducting function in part of the material and has an insulating function in another part of the material; as a whole, the CAC-OS or the CAC-metal oxide has a function of a semiconductor. In the case where the CAC-OS or the CAC-metal oxide is used in a semiconductor layer of a transistor, the conducting function is to allow electrons (or holes) serving as carriers to flow, and the insulating function is to not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

In addition, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, in some cases, the conductive regions are observed to be coupled in a cloud-like manner with their boundaries blurred.

In the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm and are dispersed in the material in some cases.

The CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used for a channel formation region of a transistor, the transistor in the on state can achieve high current driving capability, that is, a high on-state current and high field-effect mobility.

In other words, the CAC-OS or the CAC-metal oxide can also be referred to as a matrix composite or a metal matrix composite.

Oxide semiconductors (metal oxides) are classified into a single crystal oxide semiconductor and a non-single-crystal oxide semiconductor. Examples of a non-single-crystal oxide semiconductor include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that it is difficult to observe a clear crystal grain boundary (also referred to as grain boundary) even in the vicinity of distortion in the CAAC-OS. That is, formation of a crystal grain boundary is found to be inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

The CAAC-OS tends to have a layered crystal structure (also referred to as a layered structure) in which a layer containing indium and oxygen (hereinafter, an In layer) and a layer containing the element M, zinc, and oxygen (hereinafter, an (M, Zn) layer) are stacked. Note that indium and the element M can be replaced with each other, and when the element M in the (M, Zn) layer is replaced with indium, the layer can also be referred to as an (In, M, Zn) layer. Furthermore, when indium in the In layer is replaced with the element M, the layer can be referred to as an (In, M) layer.

The CAAC-OS is a metal oxide with high crystallinity. On the other hand, a clear crystal grain boundary cannot be observed in the CAAC-OS; thus, it can be said that a reduction in electron mobility due to the crystal grain boundary is less likely to occur. Entry of impurities, formation of defects, or the like might decrease the crystallinity of a metal oxide; thus, it can be said that the CAAC-OS is a metal oxide that has small amounts of impurities and defects (e.g., oxygen vacancies (also referred to as Vₒ)). Thus, a metal oxide including a CAAC-OS is physically stable. Therefore, the metal oxide including a CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

Note that indium-gallium-zinc oxide (hereinafter, referred to as IGZO) that is a kind of metal oxide containing indium, gallium, and zinc has a stable structure in some cases by being formed of the above-described nanocrystals. In particular, crystals of IGZO tend not to grow in the air and thus, a stable structure is obtained when IGZO is formed of smaller crystals (e.g., the above-described nanocrystals) rather than larger crystals (here, crystals with a size of several millimeters or several centimeters).

An a-like OS is a metal oxide having a structure between those of the nc-OS and an amorphous oxide semiconductor. The a-like OS includes a void or a low-density region. That is, the a-like OS has low crystallinity compared with the nc-OS and the CAAC-OS.

An oxide semiconductor (metal oxide) can have various structures which show different properties. Two or more of the amorphous oxide semiconductor, the polycrystalline oxide semiconductor, the a-like OS, the nc-OS, and the CAAC-OS may be included in an oxide semiconductor of one embodiment of the present invention.

A metal oxide film that functions as a semiconductor layer can be deposited by a sputtering method using either or both of an inert gas and an oxygen gas. Note that there is no particular limitation on the flow rate ratio of oxygen (the partial pressure of oxygen) at the time of depositing the metal oxide film. However, to obtain a transistor having high field-effect mobility, the flow rate ratio of oxygen (the partial pressure of oxygen) at the time of depositing the metal oxide film is preferably higher than or equal to 0% and lower than or equal to 30%, further preferably higher than or equal to 5% and lower than or equal to 30%, still further preferably higher than or equal to 7% and lower than or equal to 15%.

The energy gap of the metal oxide is preferably 2 eV or more, further preferably 2.5 eV or more, still further preferably 3 eV or more. With the use of a metal oxide having such a wide energy gap, the off-state current of the transistor can be reduced.

The transistor including the metal oxide can exhibit characteristics with an extremely low off-state current of several yoctoamperes per micrometer (a current value per micrometer of a channel width). A transistor including a metal oxide has features such that impact ionization, an avalanche breakdown, a short-channel effect, or the like does not occur, which are different from those of a transistor including Si. Thus, the use of the transistor enables formation of a highly reliable circuit. Moreover, variations in electrical characteristics due to crystallinity unevenness, which are caused in transistors including Si, are less likely to occur in the transistors including a metal oxide.

The substrate temperature during the deposition of the metal oxide film is preferably lower than or equal to 350 °C, further preferably higher than or equal to room temperature and lower than or equal to 200 °C, still further preferably higher than or equal to room temperature and lower than or equal to 130 °C. The substrate temperature during the deposition of the metal oxide film is preferably room temperature because productivity can be increased.

The metal oxide film can be formed by a sputtering method, a PLD method, a PECVD method, a thermal CVD method, an MOCVD method, an ALD method, a vacuum evaporation method, or the like.

The above is the description of the metal oxide.

At least part of this embodiment can be implemented in combination with the other embodiments described in this specification as appropriate.

### Embodiment 2

In this embodiment, a circuit of a pixel included in a display device of one embodiment of the present invention will be described.

The pixel of the display device of one embodiment of the present invention includes the subpixels 11, 12, and 13. A pixel circuit PIX1 of the subpixel 11 includes a light-emitting device that emits visible light. A pixel circuit PIX2 of the subpixel 12 includes a light-emitting device that emits near-infrared light. A pixel circuit PIX3 of the subpixel 13 includes a light-receiving device.

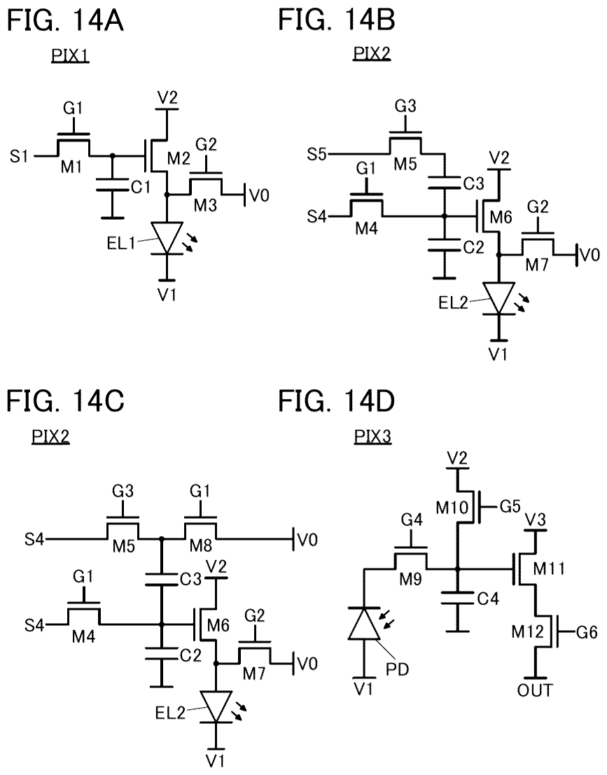

FIG. 14A illustrates an example of the pixel circuit PIX1 of the subpixel 11. The pixel circuit PIX1 includes a light-emitting device EL1, a transistor M1, a transistor M2, a transistor M3, and a capacitor C1. Here, a light-emitting diode is used as the light-emitting device EL1, for example. An organic EL element that emits visible light is preferably used as the light-emitting device EL1.

A gate of the transistor M1 is electrically connected to a wiring G1, one of a source and a drain of the transistor M1 is electrically connected to a wiring S1, and the other of the source and the drain of the transistor M1 is electrically connected to one electrode of the capacitor C1 and a gate of the transistor M2. One of a source and a drain of the transistor M2 is electrically connected to a wiring V2, and the other is electrically connected to an anode of the light-emitting device EL1 and one of a source and a drain of the transistor M3. A gate of the transistor M3 is electrically connected to a wiring G2, and the other of the source and the drain of the transistor M3 is electrically connected to a wiring V0. A cathode of the light-emitting device EL1 is electrically connected to a wiring V1.

A constant potential is supplied to each of the wiring V1 and the wiring V2. Light emission can be performed when the anode side of the light-emitting device EL1 is set to a high potential and the cathode side is set to a low potential. The transistor M1 is controlled by a signal supplied to the wiring G1 and functions as a selection transistor for controlling a selection state of the pixel circuit PIX1. The transistor M2 functions as a driving transistor that controls a current flowing through the light-emitting device EL1 in accordance with a potential supplied to the gate.

When the transistor M1 is in a conduction state, a potential supplied to the wiring S1 is supplied to the gate of the transistor M2, and the emission luminance of the light-emitting device EL1 can be controlled in accordance with the potential. The transistor M3 is controlled by a signal supplied to the wiring G2. Accordingly, a potential between the transistor M3 and the light-emitting device EL1 can be reset to a constant potential supplied from the wiring V0; thus, a potential can be written to the gate of the transistor M2 in the state where the source potential of the transistor M2 is stabilized.

FIG. 14B illustrates an example of the pixel circuit PIX2 of the subpixel 12. The pixel circuit PIX2 has a function of boosting a voltage. The pixel circuit PIX2 includes a light-emitting device EL2, a transistor M4, a transistor M5, a transistor M6, a transistor M7, a capacitor C2, and a capacitor C3. Here, a light-emitting diode is used as the light-emitting device EL2, for example. An organic EL element that emits near-infrared light is preferably used as the light-emitting device EL2. The pixel circuit PIX2 has a function of boosting a voltage to emit near-infrared light at high luminance.

A gate of the transistor M4 is electrically connected to the wiring G1, one of a source and a drain of the transistor M4 is electrically connected to a wiring S4, and the other of the source and the drain of the transistor M4 is electrically connected to one electrode of the capacitor C2, one electrode of the capacitor C3, and a gate of the transistor M6. A gate of the transistor M5 is electrically connected to a wiring G3, one of a source and a drain of the transistor M5 is electrically connected to a wiring S5, and the other of the source and the drain of the transistor M5 is electrically connected to the other electrode of the capacitor C3.

One of a source and a drain of the transistor M6 is electrically connected to the wiring V2, and the other is electrically connected to an anode of the light-emitting device EL2 and one of a source and a drain of the transistor M7. A gate of the transistor M7 is electrically connected to the wiring G2, and the other of the source and the drain of the transistor M7 is electrically connected to the wiring V0. A cathode of the light-emitting device EL2 is electrically connected to the wiring V1.

The transistor M4 is controlled by a signal supplied to the wiring G1, and the transistor M5 is controlled by a signal supplied to the wiring G3. The transistor M6 functions as a driving transistor that controls a current flowing through the light-emitting device EL2 in accordance with a potential supplied to the gate.

The emission luminance of the light-emitting device EL2 can be controlled in accordance with the potential supplied to the gate of the transistor M6. The transistor M7 is controlled by a signal supplied to the wiring G2. A potential between the transistor M6 and the light-emitting device EL2 can be reset to a constant potential supplied from the wiring V0; thus, a potential can be written to the gate of the transistor M6 in the state where the source potential of the transistor M6 is stabilized. In addition, when the potential supplied from the wiring V0 is set to the same potential as the potential of the wiring V1 or a potential lower than that of the wiring V1, light emission of the light-emitting device EL2 can be inhibited.

To increase the emission intensity of the light-emitting device EL2, a high voltage is preferably supplied to the gate of the transistor M6 in the pixel circuit PIX2. The function of boosting a voltage, which is of the pixel circuit PIX2, will be described below.

First, a potential “D1” of the wiring S4 is supplied to the gate of the transistor M6 through the transistor M4, and at timing overlapping with this, a reference potential “V_{ref}” is supplied to the other electrode of the capacitor C3 through the transistor M5. At this time, “D1−V_{ref}” is retained in the capacitor C3. Next, the gate of the transistor M6 is set to be floating, and a potential “D2”of the wiring S5 is supplied to the other electrode of the capacitor C3 through the transistor M5. Here, the potential “D2” is a potential for addition.

At this time, the potential of the gate of the transistor M6 is D1+(C₃/(C₃+C₂+C_{M6}))×(D2−V_{ref})), where the capacitance value of the capacitor C3 is C₃, the capacitance value of the capacitor C2 is C₂, and the capacitance value of the gate of the transistor M6 is C_{M6}. Here, assuming that the value of C₃ is sufficiently larger than the value of C₂+C_{M6}, C₃/(C₃+C₂+C_{M6}) approximates one. Thus, it can be said that the potential of the gate of the transistor M6 approximates “D1+(D2−V_{ref})”. Then, when D1=D2 and V_{ref}=0, “D1+(D2−V_{ref}))”=“2D1”.

That is, when the circuit is designed appropriately, a potential approximately twice as high as the potential that can be input from the wiring S4 or S5 can be supplied to the gate of the transistor M6.

Owing to such an action, a high voltage can be generated even using a general-purpose driver IC. Accordingly, the light-emitting device EL2 can emit light at high luminance.

Alternatively, the pixel circuit PIX2 may have a structure illustrated in FIG. 14C. The pixel circuit PIX2 illustrated in FIG. 14C differs from the pixel circuit PIX2 illustrated in FIG. 14B in including a transistor M8. A gate of the transistor M8 is electrically connected to the wiring G1, one of a source and a drain is electrically connected to the other of the source and the drain of the transistor M5 and the other electrode of the capacitor C3, and the other of the source and the drain is electrically connected to the wiring V0. The one of the source and the drain of the transistor M5 is connected to the wiring S4.

As described above, in the pixel circuit PIX2 illustrated in FIG. 14B, the operations of supplying the reference potential and the potential for addition to the other electrode of the capacitor C3 through the transistor M5 are performed. In this case, the two wirings S4 and S5 are necessary and the reference potential and the potential for addition need to be rewritten alternately in the wiring S5.

In the pixel circuit PIX2 illustrated in FIG. 14C, although the transistor M8 is additionally provided, the wiring S5 can be omitted because a dedicated path for supplying the reference potential is provided. Furthermore, since the gate of the transistor M8 can be connected to the wiring G1 and the wiring V0 can be used as a wiring for supplying the reference potential, a wiring connected to the transistor M8 is not additionally provided. Moreover, alternately rewriting of the reference potential and the potential for addition is not performed in one wiring, which makes it possible achieve high-speed operation with low power consumption.

Note that in FIG. 14B and FIG. 14C, “D1B”, an inversion potential of “D1”, may be used as the reference potential “V_{ref}”. In this case, a potential approximately three times as high as the potential that can be input from the wiring S4 or S5 can be supplied to the gate of the transistor M6. Note that the inversion potential refers to a potential such that the absolute value of the difference between the potential and a reference potential is the same (or substantially the same) as that of the difference between the original potential and the reference potential, and the potential is different from the original potential. The relation V₀=(D1+D1B)/2 needs to be satisfied, where the original potential is “D1”, the inversion potential is “D1B”, and the reference potential is V₀.

Note that a structure in which the light-emitting device EL2 emits light in the circuit of the pixel circuit PIX1 can be used for the subpixel 12.

In the display device of this embodiment, the light-emitting device may be made to emit light in a pulsed manner so as to display an image. A reduction in the driving time of the light-emitting device can reduce power consumption of the display device and inhibit heat generation. An organic EL element is particularly preferable because of its favorable frequency characteristics. The frequency can be greater than or equal to 1 kHz and less than or equal to 100 MHz, for example.

FIG. 14D illustrates an example of the pixel circuit PIX3 of the subpixel 13. The pixel circuit PIX3, a light-receiving device PD, a transistor M9, a transistor M10, a transistor M11, a transistor M12, and a capacitor C4 are included. Here, a photodiode is used as the light-receiving device PD, for example.

An anode of the light-receiving device PD is electrically connected to the wiring V1 and a cathode of the light-receiving device PD is electrically connected to one of a source and a drain of the transistor M9. A gate of the transistor M9 is electrically connected to a wiring G4, and the other of the source and the drain of the transistor M9 is electrically connected to one electrode of the capacitor C4, one of a source and a drain of the transistor M10, and a gate of the transistor M11. A gate of the transistor M10 is electrically connected to a wiring G5, and the other of the source and the drain of the transistor M10 is electrically connected to the wiring V2. One of a source and a drain of the transistor M11 is electrically connected to a wiring V3, and the other of the source and the drain of the transistor M11 is electrically connected to one of a source and a drain of the transistor M12. A gate of the transistor M12 is electrically connected to a wiring G6, and the other of the source and the drain of the transistor M12 is electrically connected to a wiring OUT.

A constant potential is supplied to each of the wiring V1, the wiring V2, and the wiring V3. When the light-receiving device PD is driven with a reverse bias, a potential higher than the potential of the wiring V1 is supplied to the wiring V2. The transistor M10 is controlled by a signal supplied to the wiring G5 and has a function of resetting the potential of a node connected to the gate of the transistor M11 to a potential supplied to the wiring V2. The transistor M9 is controlled by a signal supplied to the wiring G4 and has a function of controlling the timing at which the potential of the node changes, in accordance with a current flowing through the light-receiving device PD. The transistor M11 functions as an amplifier transistor that performs output corresponding to the potential of the node. The transistor M12 is controlled by a signal supplied to the wiring G6 and functions as a selection transistor for reading the output corresponding to the potential of the node by an external circuit connected to the wiring OUT.

Here, as each of the transistors M1 to M12 included in the pixel circuits PIX1 to PIX3, it is preferable to use a transistor including a metal oxide (an oxide semiconductor) for a semiconductor layer where a channel is formed.

A transistor using a metal oxide having a wider band gap and a lower carrier density than silicon can achieve an extremely low off-state current. Such a low off-state current enables retention of charges accumulated in a capacitor that is connected in series with the transistor for a long time.

Therefore, it is preferable to use transistors including an oxide semiconductor particularly as the transistor M1, the transistor M4, the transistor M5, the transistor M8, the transistor M9, and the transistor M10, in each of which one or the other of the source and the drain is connected to the capacitor C1, the capacitor C2, the capacitor C3, or the capacitor C4. With the use of transistors including an oxide semiconductor in the subpixel 13, a global shutter system, in which all the pixels perform an operation of accumulating charge at the same time, can be used without complicated circuits structure and driving methods.

Moreover, the use of transistors including an oxide semiconductor as the other transistors can reduce the manufacturing cost.

Alternatively, transistors using silicon as a semiconductor in which a channel is formed can be used as the transistors M1 to M12. In particular, the use of silicon with high crystallinity, such as single crystal silicon or polycrystalline silicon, is preferable because high field-effect mobility is achieved and higher-speed operation is possible.

Alternatively, a transistor including an oxide semiconductor may be used as at least one of the transistors M1 to M12, and transistors including silicon may be used as the other transistors.

Although FIG. 14A to FIG. 14D each illustrate an example in which n-channel transistors are used, p-channel transistors can also be used.

The transistors included in the pixel circuit PIX1, the transistors included in the pixel circuit PIX2, and the transistors included in the pixel circuit PIX3 are preferably formed side by side over the same substrate. In addition, of the wirings connected to the pixel circuits PIX1 to PIX3, wirings that are denoted by the same reference numeral in FIG. 14A to FIG. 14D may be a common wiring.

One or more layers including the transistor and/or the capacitor are preferably provided to overlap with the light-receiving device PD, the light-emitting device EL1, or the light-emitting device EL2. Thus, the effective area of each pixel circuit can be reduced, and a high-definition light-receiving portion or display portion can be achieved.

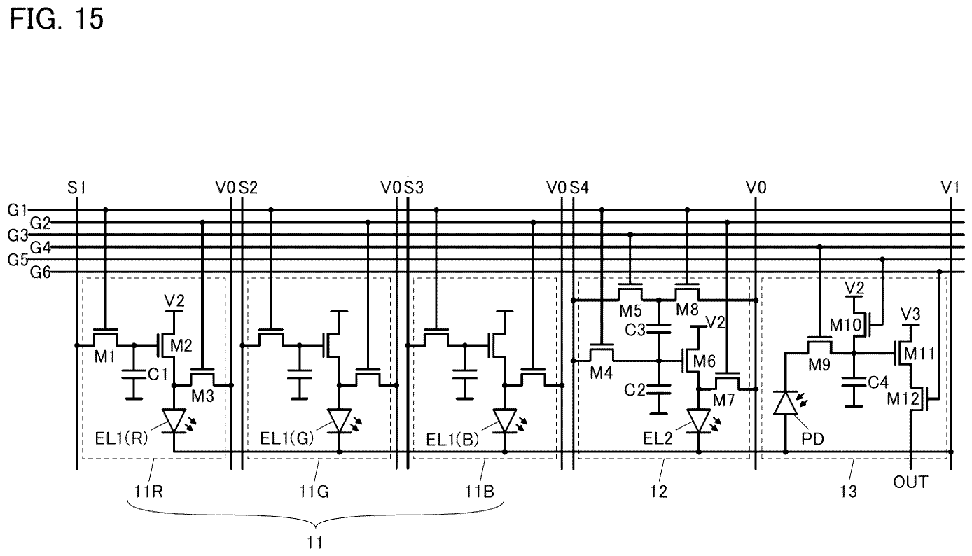

FIG. 15 is an example of a circuit diagram of the subpixel 11 (the subpixel 11R, the subpixel 11G, and the subpixel 11B), the subpixel 12, and the subpixel 13 included in the pixel 10. The wirings G1 to G3 can be electrically connected to the gate driver (FIG. 1, the circuit 16). The wirings G4 to G6 can be electrically connected to the row driver (FIG. 1, the circuit 18). The wirings S1 to S4 can be electrically connected to the source driver (FIG. 1, the circuit 15). The wiring OUT can be electrically connected to the column driver (FIG. 1, the circuit 17) and the reading circuit (FIG. 1, the circuit 19).

A power supply circuit that supplies a constant potential can be electrically connected to the wirings V0 to V3, a low potential can be supplied to the wirings V0 and V1, and a high potential can be supplied to the wirings V2 and V3. Note that the wiring S4 may be electrically connected not to the source driver but to a circuit that supplies a constant potential. The wiring V2 and the wiring V3 may be common.

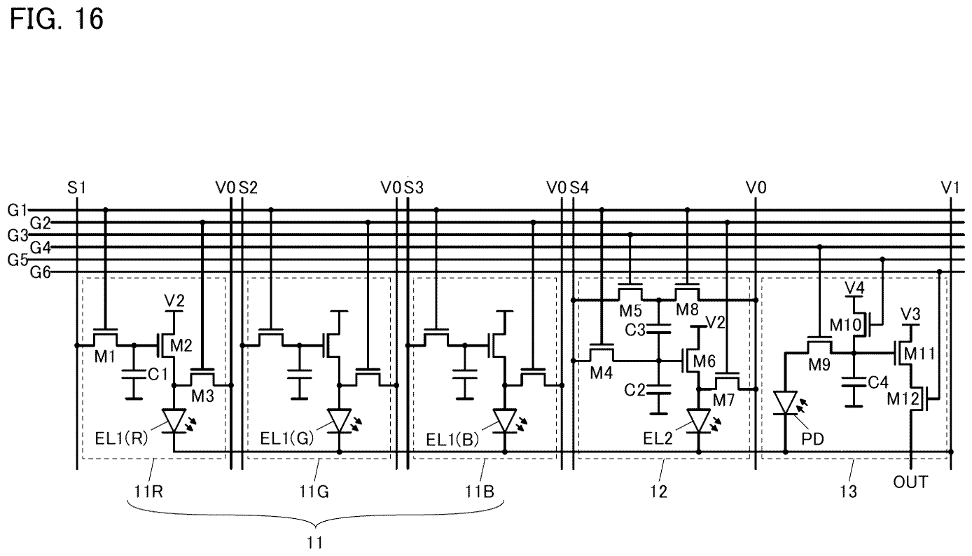

The cathode of the light-receiving device PD in the subpixel 13 may be electrically connected to the wiring V1, and the other of the source and the drain of the transistor M10 may be electrically connected to a wiring V4, as illustrated in FIG. 16. At this time, the wiring V4 can supply a potential lower than the potential supplied to the wiring V1.

In one embodiment of the present invention, a power supply line or the like can be shared by the subpixel 11, the subpixel 12, and the subpixel 13.

At least part of this embodiment can be implemented in combination with the other embodiments described in this specification as appropriate.

### Embodiment 3

In this embodiment, electronic devices of embodiments of the present invention will be described.

An electronic device of this embodiment includes the display device of one embodiment of the present invention. For example, the display device of one embodiment of the present invention can be used in a display portion of the electronic device. Since the display device of one embodiment of the present invention has a function of detecting light, the display device can perform an input operation regardless of whether with or without contact. In addition, biological authentication can be performed with the use of an imaging function of the display portion. Accordingly, the electronic device can have improved functionality and convenience, for example.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

The electronic device of this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

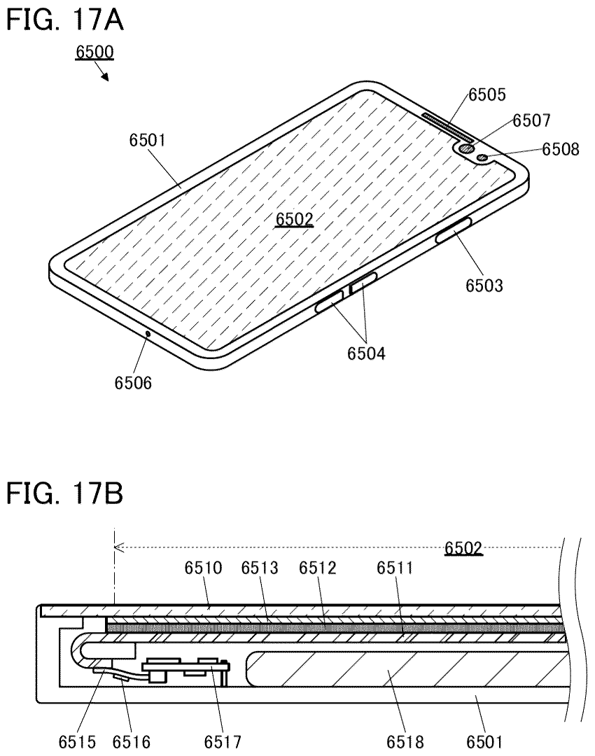

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 17B is a schematic cross-sectional view including an end portion of the housing 6501 on the microphone 6506 side.

A protective member 6510 that transmits light is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with an adhesive layer (not illustrated). Note that the display device of one embodiment of the present invention can be used in the display panel 6511, and the touch sensor panel 6513 may be omitted in the case where only a sensor function of the display device is used.

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device with flexibility of one embodiment of the present invention can be used for the display panel 6511. Thus, an extremely lightweight electronic device can be achieved. Since the display panel 6511 is extremely thin, the battery 6518 with high capacity can be mounted with the thickness of the electronic device controlled. An electronic device with a narrow frame can be achieved when part of the display panel 6511 is folded back so that the portion connected to the FPC 6515 is positioned on the rear side of a pixel portion.

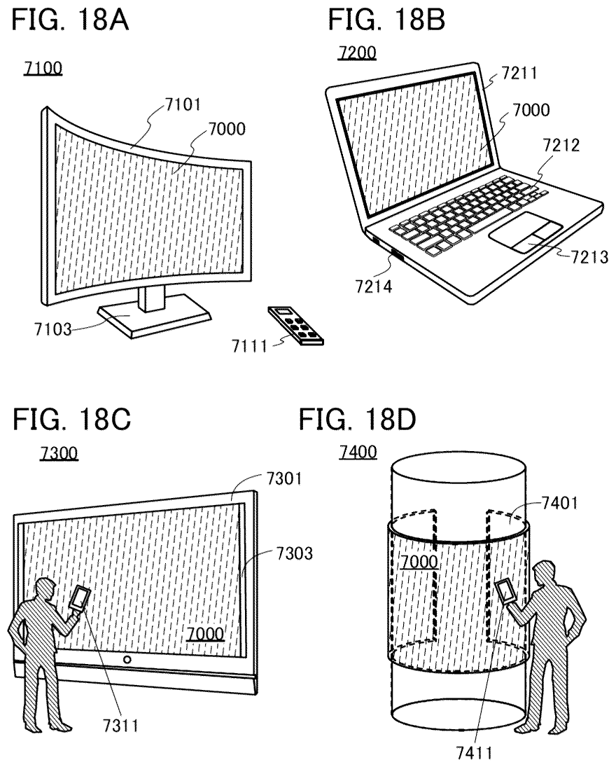

FIG. 18A illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used in the display portion 7000.

Operation of the television device 7100 illustrated in FIG. 18A can be performed with an operation switch provided in the housing 7101 or a separate remote controller 7111. Alternatively, the television device 7100 may be operated in such a manner that the touch sensor or the near-touch sensor provided in the display portion 7000 is made to function and a finger or the like touches or is made closer to the display portion 7000. The remote controller 7111 may be provided with a display unit for displaying information output from the remote controller 7111. With operation keys or a touch panel provided in the remote controller 7111, channels and volume can be operated and images displayed on the display portion 7000 can be operated.

Note that the television device 7100 is provided with a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 18B illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 18C and FIG. 18D illustrate examples of digital signage.

Digital signage 7300 illustrated in FIG. 18C includes a housing 7301, the display portion 7000, a speaker 7303, and the like. Furthermore, the digital signage can include an LED lamp, operation keys (including a power switch or an operation switch), a connection terminal, a variety of sensors, a microphone, and the like.

FIG. 18D is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 18C and FIG. 18D.

A larger area of the display portion 7000 can increase the amount of information that can be provided at a time. The larger display portion 7000 attracts more attention, so that the effectiveness of the advertisement can be increased, for example.

When the touch sensor or the near-touch sensor provided in the display portion 7000 is made to function, not only display of an image or a moving image on the display portion 7000 but also intuitive operation by the user is possible. Moreover, for an application for getting information such as route information or traffic information, usability can be enhanced by intuitive operation.

As illustrated in FIG. 18C and FIG. 18D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

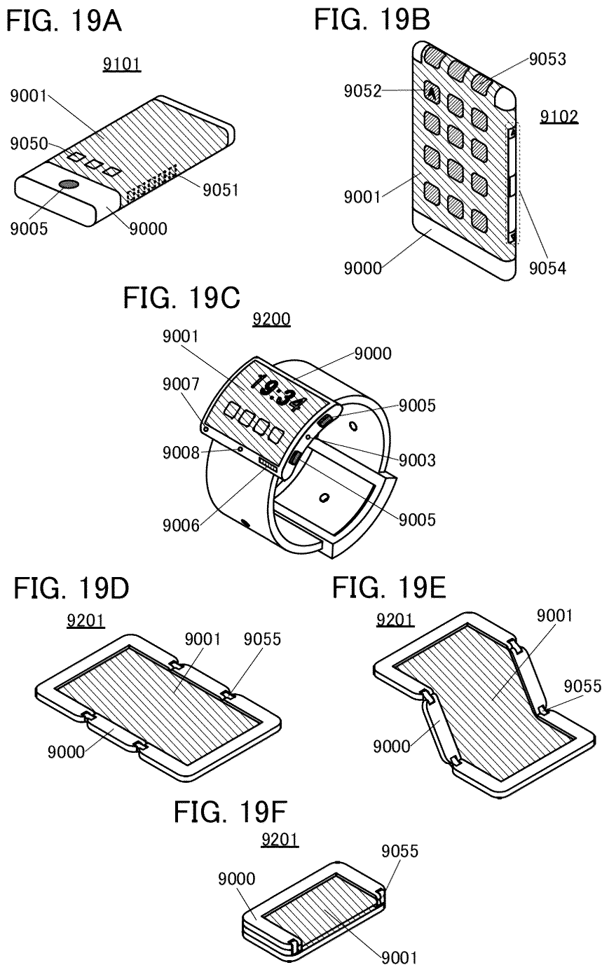

Electronic devices illustrated in FIG. 19A to FIG. 19F include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 19A to FIG. 19F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may each include a camera or the like and have a function of taking a still image or a moving image and storing the taken image in a recording medium (external or incorporated in the camera), a function of displaying the taken image on the display portion, or the like.

The details of the electronic devices illustrated in FIG. 19A to FIG. 19F are described below. When the display device of one embodiment of the present invention is used in the electronic devices illustrated in FIG. 19A to FIG. 19F, an input function is possible even without contact.

FIG. 19A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 19A illustrates an example where three icons 9050 are displayed. Information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the reception strength of an antenna. Alternatively, the icon 9050 or the like may be displayed in the position where the information 9051 is displayed.

FIG. 19B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed at a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 19C is a perspective view illustrating a watch-type portable information terminal 9200. For example, the portable information terminal 9200 can be used as a smart watch. The display surface of the display portion 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 19D, FIG. 19E, and FIG. 19F are perspective views illustrating a foldable portable information terminal 9201. FIG. 19D is a perspective view of an opened state of the portable information terminal 9201, FIG. 19F is a perspective view of a folded state thereof, and FIG. 19E is a perspective view of a state in the middle of change from one of FIG. 19D and FIG. 19F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature of greater than or equal to 0.1 mm and less than or equal to 150 mm.

At least part of this embodiment can be implemented in combination with the other embodiments described in this specification as appropriate.

### REFERENCE NUMERALS

10: pixel, 11: subpixel, 11B: subpixel, 11G: subpixel, 11R: subpixel, 12: subpixel, 13: subpixel, 14: pixel array, 15: circuit, 16: circuit, 17: circuit, 18: circuit, 19: circuit, 20: light source, 21: light, 22: light, 23a: light, 23b: reflected light, 23c: light, 23d: reflected light, 41: transistor, 42: transistor, 50A: display device, 50B: display device, 50C: display device, 50D: display device, 50E: display device, 60: object, 100A: display device, 100B: display device, 100C: display device, 100D: display device, 110: light-receiving device, 111: pixel electrode, 112: common layer, 113: photoelectric conversion layer, 114: common layer, 115: common electrode, 142: adhesive layer, 143: space, 148: light-blocking layer, 149: filter, 151: substrate, 152: substrate, 153: substrate, 154: substrate, 155: adhesive layer, 162: display portion, 164a: circuit, 164b: circuit, 165: wiring, 165a: wiring, 165b: wiring, 166: conductive layer, 172a: FPC, 172b: FPC, 173a: IC, 173b: IC, 180: light-emitting device, 182: buffer layer, 183: light-emitting layer, 184: buffer layer, 190: light-emitting device, 191: pixel electrode, 192: buffer layer, 193: light-emitting layer, 194: buffer layer, 195: protective layer, 195a: inorganic insulating layer, 195b: organic insulating layer, 195c: inorganic insulating layer, 201: transistor, 204: connection portion, 205: transistor, 206: transistor, 208: transistor, 209: transistor, 210: transistor, 211: insulating layer, 212: insulating layer, 213: insulating layer, 214: insulating layer, 215: insulating layer, 216: partition, 217: partition, 218: insulating layer, 221: conductive layer, 222a: conductive layer, 222b: conductive layer, 223: conductive layer, 225: insulating layer, 228: region, 231: semiconductor layer, 231i: channel formation region, 231n: low-resistance region, 242: connection layer, 6500: electronic device, 6501: housing, 6502: display portion, 6503: power button, 6504: button, 6505: speaker, 6506: microphone, 6507: camera, 6508: light source, 6510: protective member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. A display device comprising:
a first subpixel, a second subpixel, and a third subpixel,
wherein the first subpixel includes a first transistor, a second transistor, and a first light-emitting device,
wherein the second subpixel includes a third transistor, a fourth transistor, a fifth transistor, a first capacitor, a second capacitor, and a second light-emitting device,
wherein the third subpixel includes a sixth transistor, a seventh transistor, an eighth transistor, and a light-receiving device,
wherein the first light-emitting device is configured to emit visible light,
wherein the second light-emitting device is configured to emit near-infrared light,
wherein the light-receiving device is configured to detect the near-infrared light,
wherein the first transistor is configured to supply a first potential to a gate of the second transistor,
wherein the second transistor is configured to be a driving transistor which controls a current flowing through the first light-emitting device in accordance with the first potential,
wherein one of a source and a drain of the third transistor is electrically connected to a gate of the fourth transistor,
wherein the gate of the fourth transistor is electrically connected to one electrode of the first capacitor, and to one electrode of the second capacitor,
wherein one of a source and a drain of the fifth transistor is electrically connected to the other electrode of the second capacitor,
wherein one of an anode and a cathode of the light-receiving device is electrically connected to one of a source and a drain of the sixth transistor,
wherein the other of the source and the drain of the sixth transistor is electrically connected to a gate of the seventh transistor,
wherein one of a source and a drain of the seventh transistor is electrically connected to one of a source and a drain of the eighth transistor,
wherein the seventh transistor is configured to be an amplifier transistor which performs output corresponding to a second potential supplied to the gate of the seventh transistor, and
wherein the second subpixel is configured to perform light emission of the second light-emitting device by controlling a current flowing through the fourth transistor in accordance with a fifth potential which was boosted from a third potential supplied to the one electrode of the first capacitor through the third transistor by supplying a fourth potential to the other electrode of the second capacitor through the fifth transistor.

2. The display device according to claim 1,
wherein the first subpixel and the second subpixel are provided in a first pixel,
wherein the third subpixel is provided in a second pixel,
wherein the first pixel does not have a light-receiving device, and
wherein the second pixel does not have a light-emitting device emitting a near-infrared light.

3. The display device according to claim 1, wherein the first light-emitting device emits at least one of red light, green light, blue light, and white light.

4. The display device according to claim 1,
wherein the light-receiving device includes a photoelectric conversion layer, and
wherein the photoelectric conversion layer includes an organic compound.

5. The display device according to claim 1, further comprising a filter which filters out visible light in a position overlapping with the light-receiving device.

6. The display device according to claim 1,
wherein a channel formation region of each of the first transistor, the second transistor, the third transistor, the fourth transistor, the fifth transistor, the sixth transistor, the seventh transistor, and the eighth transistor includes a metal oxide,
wherein the metal oxide includes In, Zn, and M, and
wherein M includes at least one of Al, Ti, Ga, Ge, Sn, Y, Zr, La, Ce, Nd, and Hf.

7. An electronic device including a camera, and the display device according to claim 1.
